(19) United States
(12) Patent Application Publication
(10) Pub. No.: US 2025/0374536 A1
(43) Pub. Date: Dec. 4, 2025

(54) MICROELECTRONIC DEVICES INCLUDING SHIELD STRUCTURES, AND RELATED MEMORY DEVICES AND ELECTRONIC SYSTEMS

(71) Applicant: Micron Technology, Inc., Boise, ID (US)

(72) Inventors: Fatma Arzum Simsek-Ege, Boise, ID (US); Steve V. Cole, Boise, ID (US); Toby D. Robbs, Boise, ID (US); Christopher K. Morzano, Boise, ID (US)

(21) Appl. No.: 19/195,424

(22) Filed: Apr. 30, 2025

Related U.S. Application Data
(60) Provisional application No. 63/654,655, filed on May 31, 2024.

(51) Int. Cl. H10B 12/00

(52) U.S. Cl. CPC H10B 12/50; H10B 12/036; H10B 12/05; H10B 12/33

(57) ABSTRACT

A microelectronic device includes a first memory array structure including a first array region including first memory cells within a horizontal area of the first array region, each of the first memory cells having a first access device and a first storage node device vertically underlying and coupled to the first access device, a first control circuitry structure vertically overlying and attached to the first memory array structure at a boundary of the first memory array structure vertically closer to the first access devices of the first memory cells than the first storage node devices of the first memory cells, and a first shield structure vertically interposed between the first memory cells of the first memory array structure and the first control circuitry structure.

### CROSS-REFERENCE TO RELATED APPLICATIONS

This application claims the benefit under 35 U.S.C. § 119(e) of U.S. Provisional Patent Application Ser. No. 63/654,655, filed May 31, 2024, the disclosure of which is hereby incorporated herein in its entirety by this reference.

This application is also related to U.S. Patent Application Ser. No. 63/654,681 (attorney docket No. 2269-P17958US), filed May 31, 2024, listing Fatma Arzum Simsek-Ege as inventor, for “METHODS OF FORMING MICROELECTRONIC DEVICES, AND RELATED MICROELECTRONIC DEVICES.” The disclosure of the foregoing document is hereby incorporated herein in its entirety by reference.

### TECHNICAL FIELD

The disclosure, in various embodiments, relates generally to the field of microelectronic device design and fabrication. More specifically, the disclosure relates to methods of forming microelectronic devices from independently formed microelectronic device structures, and to related microelectronic devices and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often desire to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, volatile memory devices, such as dynamic random-access memory (DRAM) devices; and non-volatile memory devices such as NAND Flash memory devices. A typical memory cell of a DRAM device includes one access device, such as a transistor, and one memory storage structure, such as a capacitor. Modern applications for semiconductor devices can employ significant quantities of memory cells, arranged in memory arrays exhibiting rows and columns of the memory cells. The memory cells may be electrically accessed through digit lines (e.g., bit lines, data lines) and word lines (e.g., access lines) arranged along the rows and columns of the memory cells of the memory arrays. Memory arrays can be two-dimensional (2D) so as to exhibit a single deck (e.g., a single tier, a single level) of the memory cells, or can be three-dimensional (3D) so as to exhibit multiple decks (e.g., multiple levels, multiple tiers) of the memory cells.

Control logic devices within a base control logic structure underlying a memory array of a memory device have been used to control operations (e.g., access operations, read operations, write operations) of the memory cells of the memory device. An assembly of the control logic devices may be provided in electrical communication with the memory cells of the memory array by way of routing and interconnect structures. However, processing conditions (e.g., temperatures, pressures, materials) for the formation of the memory array over the base control logic structure can limit the configurations and performance of the control logic devices within the base control logic structure. In addition, the quantities, dimensions, and arrangements of the different control logic devices employed within the base control logic structure can also undesirably impede reductions to the size (e.g., horizontal footprint) of the memory device, and/or improvements in the performance (e.g., faster memory cell ON/OFF speed, lower threshold switching voltage requirements, faster data transfer rates, lower power consumption) of the memory device. Furthermore, as the density and complexity of the memory array have increased, so has the complexity of the control logic devices. In some instances, the control logic devices consume more real estate than the memory devices, reducing the memory density of the memory device. Moreover, capacitors for regulating and supplying voltages to the control logic devices can require substantial footprints.

### BRIEF DESCRIPTION THE DRAWINGS

FIG. 1A through FIG. 1S include simplified, perspective view of a microelectronic device structure at different processing stages of a method of forming a microelectronic device, according to one or more embodiments of the disclosure;

FIG. 2A shows a simplified, partial plan view of a memory array structure at a processing stage of a method of forming a microelectronic device, according to one or more embodiments of the disclosure. FIG. 2B shows a diagram showing different vertical cross-sectional views of the memory array structure shown in FIG. 2A, taken about lines A-A and B-B of FIG. 2A;

FIG. 3A shows a simplified partial plan view of a control circuitry structure at a processing stage of the method of forming a microelectronic device, in accordance with embodiments of the disclosure. FIG. 3B shows a diagram depicting different vertical cross-sectional views of the control circuitry structure shown in FIG. 3A, taken about lines A″-A″ and B″-B″ of FIG. 3A. FIG. 3C shows a diagram depicting different vertical cross-sectional views of a second assembly formed to include the control circuitry structure shown in FIG. 3B at a processing stage of the method of forming a microelectronic device following the processing stage of FIG. 3B. FIG. 3D shows a diagram depicting different vertical cross-sectional views of the second assembly at a processing stage following that of FIG. 3C;

FIG. 4 shows a diagram depicting different vertical cross-sectional views of a microelectronic device at a processing stage of the method of forming a microelectronic device following the processing stage of FIG. 2A and FIG. 2B and FIG. 3A through FIG. 3D, according to one or more embodiments of the disclosure;

FIG. 5 shows a diagram depicting different vertical cross-sectional views of a microelectronic device at a processing stage of a method of forming a microelectronic device, according to one or more embodiments of the disclosure;

FIG. 6 shows a schematic top view of a microelectronic device at a processing stage of a method of forming a microelectronic device, according to one or more embodiments of the disclosure; and

FIG. 7 is a schematic block diagram of an electronic system, in accordance with an embodiment of the disclosure.

### DETAILED DESCRIPTION

The illustrations included herewith are not meant to be actual views of any particular systems, microelectronic structures, microelectronic devices, or integrated circuits thereof, but are merely idealized representations that are employed to describe embodiments herein. Elements and features common between figures may retain the same numerical designation except that, for ease of following the description, reference numerals begin with the number of the drawing on which the elements are introduced or most fully described.

The following description provides specific details, such as material types, material thicknesses, and processing conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete process flow for manufacturing a microelectronic device (e.g., a semiconductor device, a memory device), apparatus, or electronic system, or a complete microelectronic device, apparatus, or electronic system. The structures described below do not form a complete microelectronic device, apparatus, or electronic system. Only those process acts and structures necessary to understand the embodiments described herein are described in detail below. Additional acts to form a complete microelectronic device, apparatus, or electronic system from the structures may be performed by conventional techniques.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

The materials described herein may be formed by conventional techniques including, but not limited to, spin coating, blanket coating, chemical vapor deposition (CVD), atomic layer deposition (ALD), plasma-enhanced ALD, physical vapor deposition (PVD), plasma-enhanced chemical vapor deposition (PECVD), or low-pressure chemical vapor deposition (LPCVD). Alternatively, the materials may be grown in situ. Depending on the specific material to be formed, the technique for depositing or growing the material may be selected by a person of ordinary skill in the art. The removal of materials may be accomplished by any suitable technique including, but not limited to, etching, abrasive planarization (e.g., chemical-mechanical planarization), or other known methods unless the context indicates otherwise.

As used herein, the term “configured” refers to a size, shape, material composition, orientation, and arrangement of one or more of at least one structure and at least one apparatus facilitating operation of one or more of the structure and the apparatus in a predetermined way.

As used herein, the terms “longitudinal,” “vertical,” “lateral,” and “horizontal” are in reference to a major plane of a substrate (e.g., base material, base structure, base construction, etc.) in or on which one or more structures and/or features are formed and are not necessarily defined by Earth's gravitational field. A “lateral” or “horizontal” direction is a direction that is substantially parallel to the major plane of the substrate, while a “longitudinal” or “vertical” direction is a direction that is substantially perpendicular to the major plane of the substrate. The major plane of the substrate is defined by a surface of the substrate having a relatively large area compared to other surfaces of the substrate. With reference to the figures, a “horizontal” or “lateral” direction may be perpendicular to an indicated “Z” axis and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the term “proximate,” when utilized to describe positions of elements relative to each other, means that the elements are relatively close or near to each other. For example, where a first element is proximate a horizontal boundary of a second element, the first element is closer to that horizontal boundary than other horizontal boundaries of the second element.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped, etc.) and the spatially relative descriptors used herein interpreted accordingly.

As used herein, features (e.g., regions, materials, structures, devices) described as “neighboring” one another means and includes features of the disclosed identity (or identities) that are located most proximate (e.g., closest to) one another. Additional features (e.g., additional regions, additional materials, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, the term “memory device” means and includes microelectronic devices exhibiting memory functionality, but not necessarily limited to memory functionality. Stated another way, and by way of example only, the term “memory device” means and includes not only conventional memory (e.g., conventional volatile memory, such as conventional DRAM; conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively doped polysilicon, conductively doped germanium (Ge), conductively doped silicon germanium (SiGe)). In addition, a “conductive structure” means and includes a structure formed of and including a conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including an insulative material.

As used herein, the term “sacrificial material” means and includes a material that is formed and/or employed during a fabrication process but which is subsequently removed, in whole or in part, prior to completion of the fabrication process. A “partially sacrificial” material means and includes a sacrificial material from which only one or more portions is or are removed prior to completion of the fabrication process. A “wholly sacrificial” material means and includes a sacrificial material that is substantially entirely removed prior to completion of the fabrication process.

As used herein, “semiconductor material” and “semiconductive material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., AlₓGa₁₋ₓAs), and quaternary compound semiconductor materials (e.g., GaₓIn₁₋ₓAs_{y}P_{1-y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions.

Unless the context indicates otherwise, the materials described herein may be formed by any suitable technique including, but not limited to, spin coating, blanket coating, chemical vapor deposition (CVD), plasma-enhanced CVD (PECVD), atomic layer deposition (ALD), plasma-enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

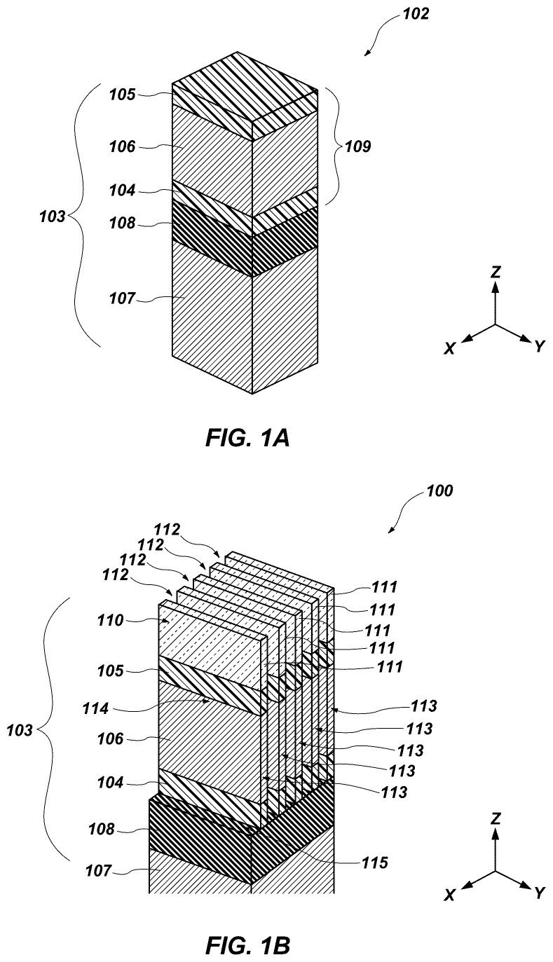

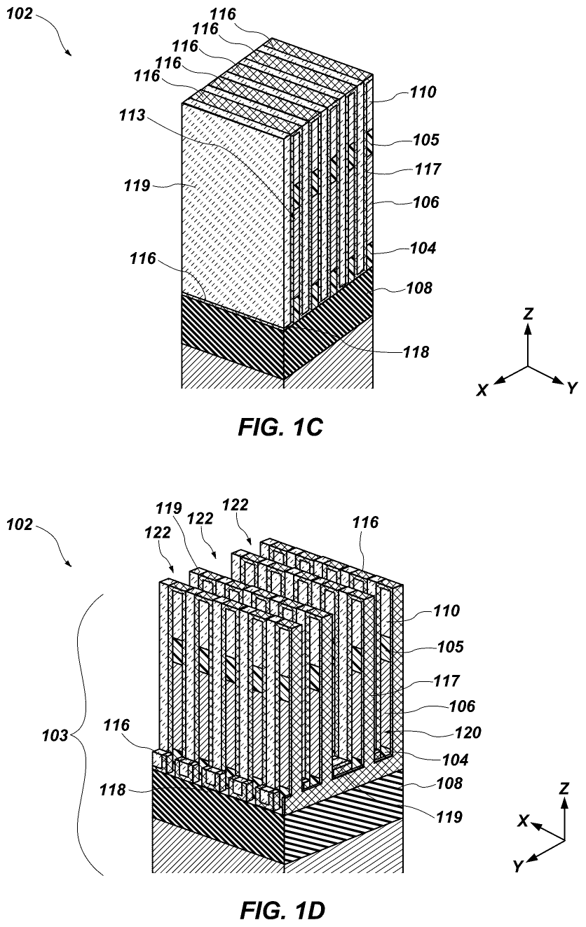

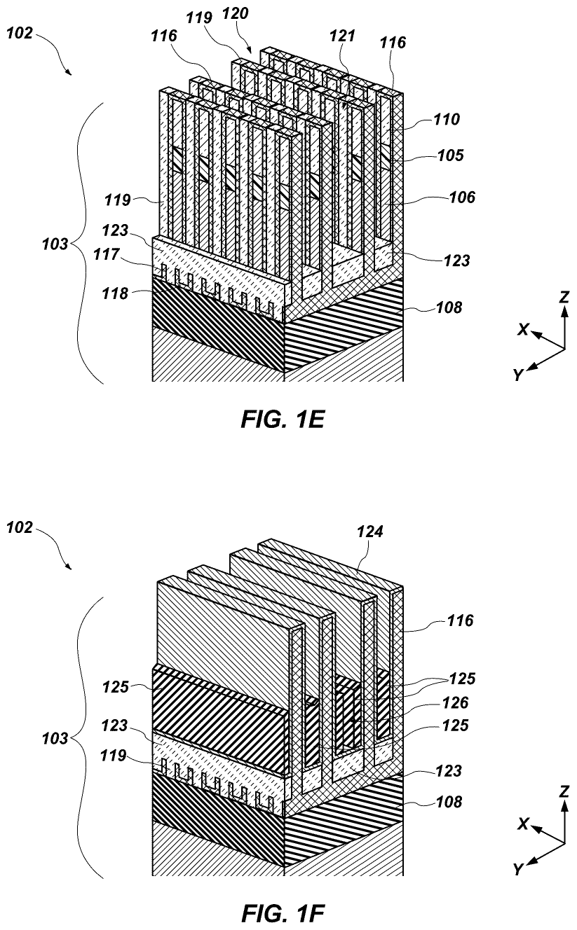

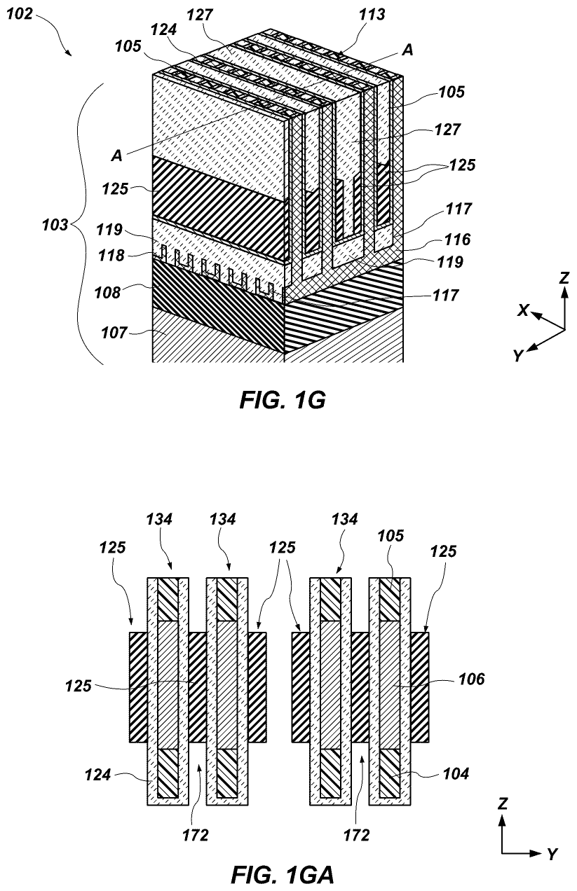

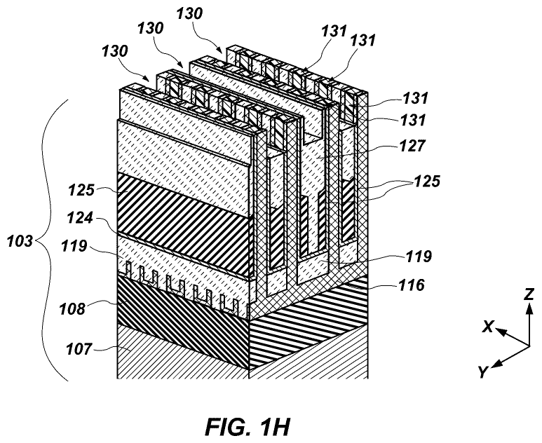

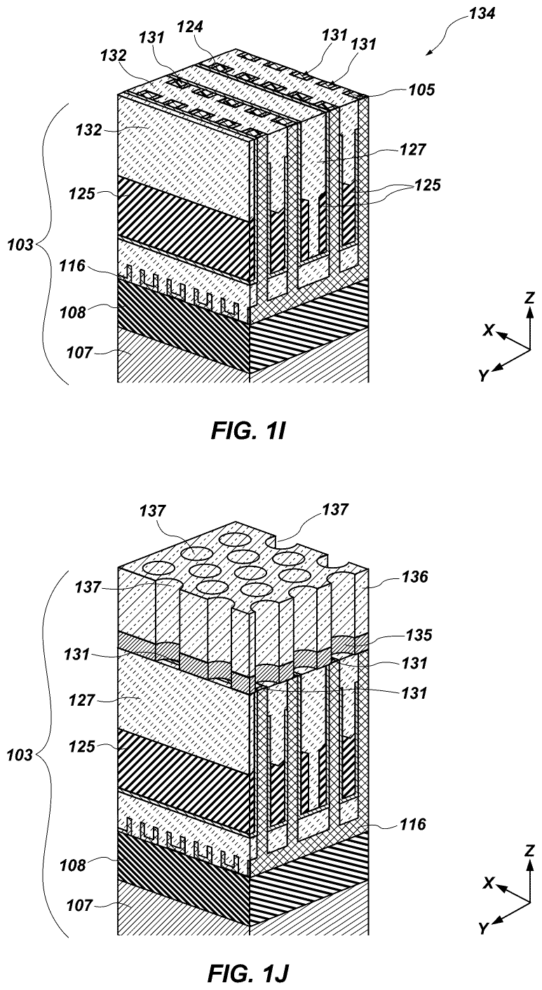

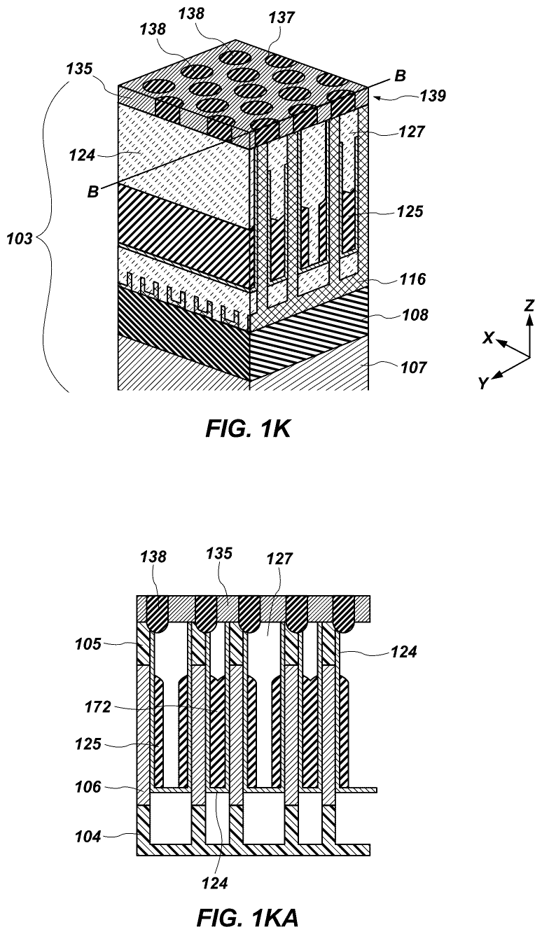

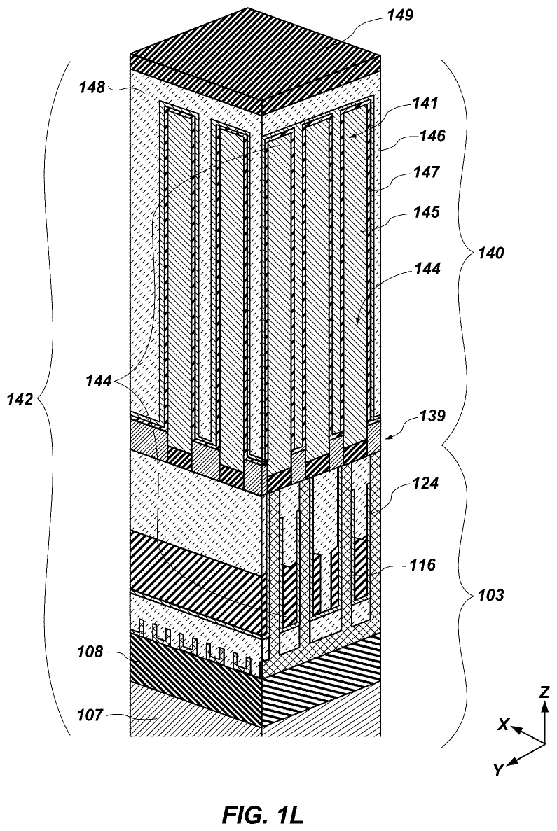

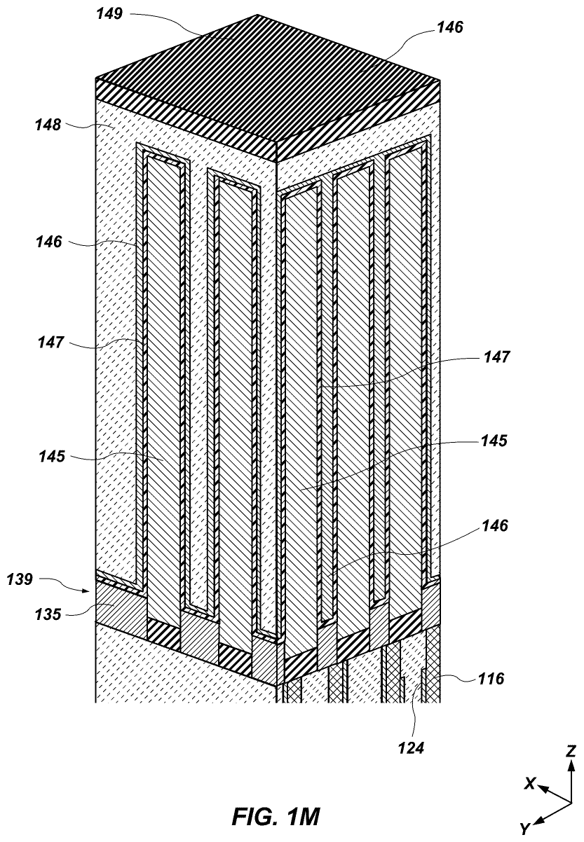

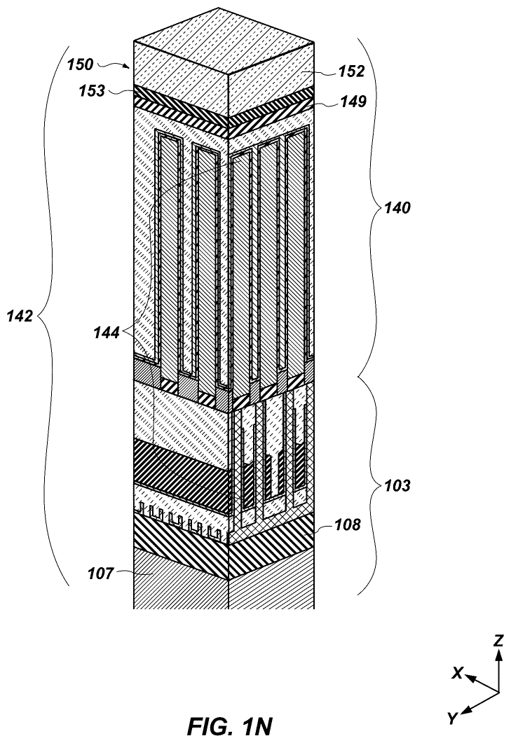

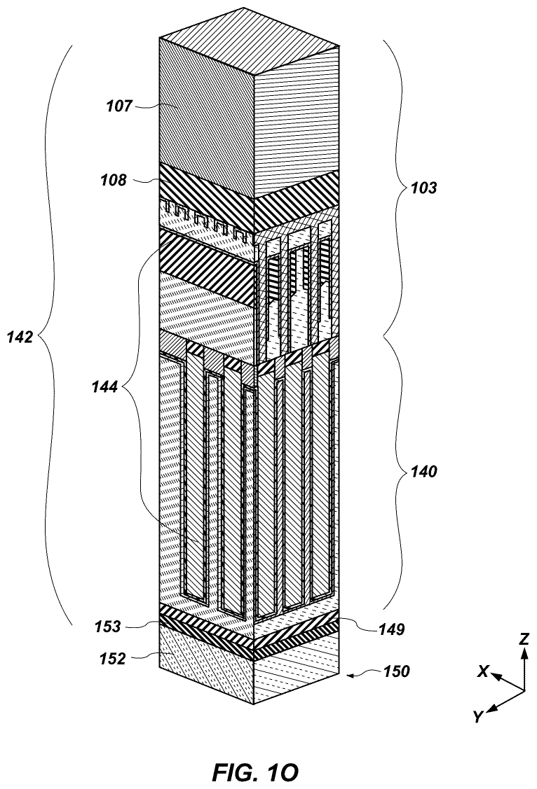

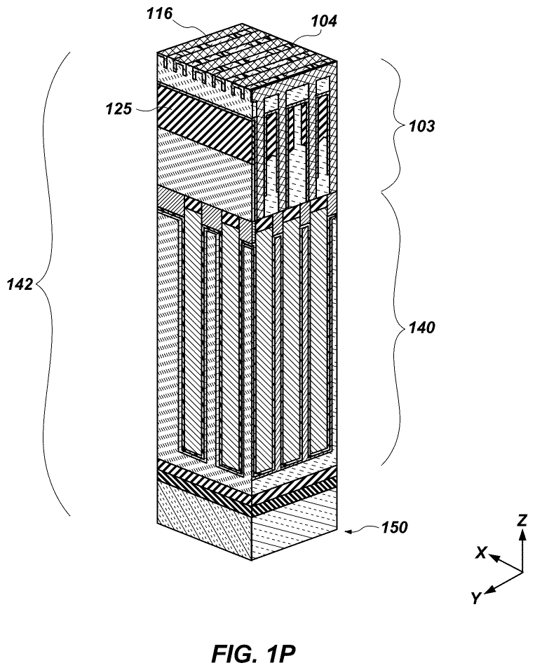

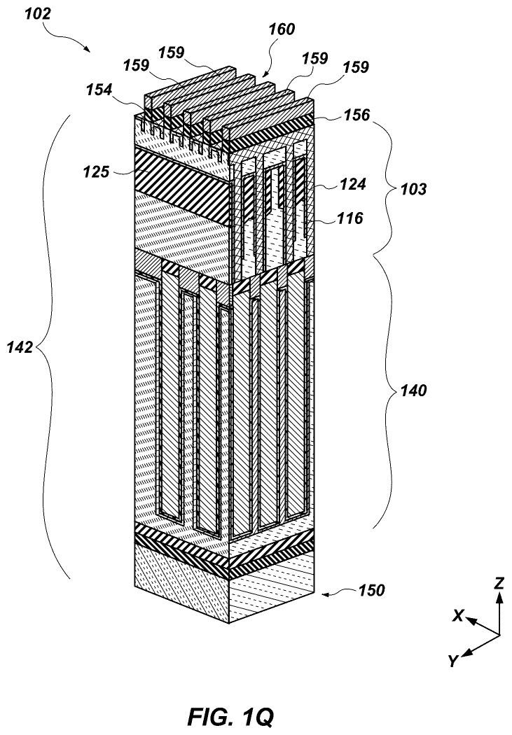

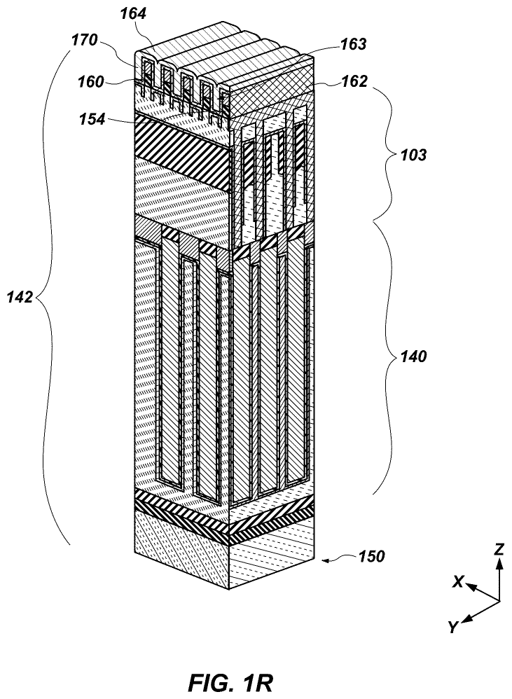

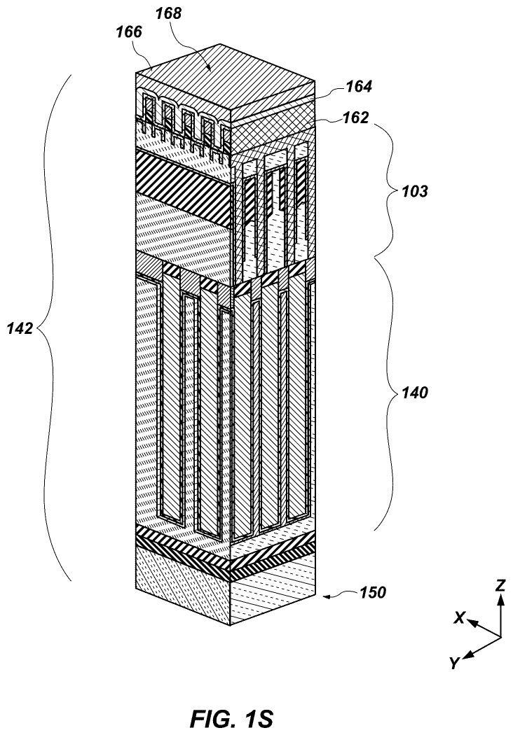

FIG. 1A through FIG. 1S include simplified, perspective views of a memory array structure 102 at different processing stages of a method of forming a microelectronic device (e.g., a memory device, such as Dynamic Random-Access Memory (DRAM) device, an HRAM device, an FeRAM device, an SDRAM device, an MRAM device), in accordance with embodiments of the disclosure. With the description provided below, it will be readily apparent to one of ordinary skill in the art that the methods described herein may be used for forming various devices.

Referring to FIG. 1A, forming a memory array structure 102 may include forming a first assembly 103. The first assembly 103 may also be referred to herein as a die or a wafer. The first assembly 103 may at least include a semiconductor structure 109 (e.g., a semiconductor wafer), or a base semiconductive material on a support structure or construction upon which additional materials and structures of the memory array structure 102 are formed. In some embodiments, the first assembly 103 includes a first base structure 107 (e.g., a silicon substrate), an insulative structure 108 formed on or over the first base structure 107, and a semiconductor structure 109 formed on or over the insulative structure 108. The semiconductor structure 109 may include a semiconductor material; and, together with the insulative structure 108, may form a silicon-over-insulator (SOI) substrate.

The semiconductor structure 109 may include a silicon structure, such as an epitaxial silicon structure. Additionally, the semiconductor structure 109 may include a first doped region 104 vertically overlying the insulative structure 108, an undoped region 106 vertically overlying the first doped region 104, and a second doped region 105 vertically overlying the undoped region 106. In some embodiments, each of the first doped region 104 and the second doped region 105 are n-type doped, such as N-type doped to an N-type dopant concentration within a range of from about 10¹⁵ cm⁻³ to about 10²⁰ cm⁻³. In additional embodiments, one of the first doped region 104 and the second doped region 105 may be N-type doped while the other of the first doped region 104 and the second doped region 105 may be P-type doped, such as P-type doped to a P-type dopant concentration within a range of from about −10¹³ cm⁻³ to about −10¹⁸ cm⁻³. In additional embodiments, one or more of the first doped region 104 is doped (either P-doped or N-doped) to the point of saturation (e.g., greater than or equal to about −10¹⁸ cm⁻³). The doping may be accomplished utilizing any suitable processing, such as by implanting dopant (e.g., at least one N-type dopant or at least one P-type dopant) into the semiconductor structure 109. A P-type dopant may include one or more of boron, aluminum, and gallium; and an N-type dopant may include one or more of arsenic, phosphorous, antimony, and bismuth.

In some embodiments, the undoped region 106 does not include any P-type dopants or any N-type dopants. In alternative embodiments, the undoped region 106 is doped with one of the dopants described herein and become another doped region.

As is discussed in further detail below, in some embodiments, the first doped region 104 forms a drain region of a later-formed vertical channel transistor (VCT), the undoped region 106 forms a channel region of the later-formed VCT, and the second doped region 105 forms a source region of the later-formed VCT.

Referring next to FIG. 1B, a first mask material 110 may be formed over the second doped region 105, and the first mask material 110 may be patterned to form first patterned masking lines 111 horizontally extending in parallel with one another in the Y-direction. The first mask material 110 may be patterned into the first patterned masking lines 111 utilizing any suitable methodology. For instance, in some embodiments, a photoresist material is formed on or over the first mask material 110, is patterned (e.g., photo exposed and developed), and then openings formed in the patterned photoresist material are extended into the first mask material 110 to form the first patterned masking lines 111. The first patterned masking lines 111 may be removed during subsequent processing stages or may remain in a final device formed through the methods of the disclosure. The first mask material 110 may be formed of and include a dielectric material, such as a dielectric nitride material (e.g., silicide nitride).

The first patterned masking lines 111 may be employed to form trenches 112 extending vertically into the first assembly 103 and the semiconductor structure 109 of the memory array structure 102. The trenches 112 may extend horizontally in parallel in the Y-direction (e.g., a first direction) and may be referred to herein as “y-axis trenches 112.” The y-axis trenches 112 may have any suitable dimensions. In some embodiments, the y-axis trenches 112 have vertical depths (e.g., vertical heights) within a range of from about 100 nm to about 200 nm (e.g., about 150 nm).

The formation of the y-axis trenches 112 effectuates the formation of semiconductor projections 113 from the semiconductor structure 109. The semiconductor projections 113 have semiconductor side surfaces 114 that are exposed by the y-axis trenches 112. Additionally, upper surfaces 115 of the insulative structure 108 extending between lower boundaries the semiconductor side surfaces 114 may also be exposed by the y-axis trenches 112.

In some embodiments, the y-axis trenches 112 are formed using an etching process (e.g., an anisotropic etching process) that selectively removes exposed portions of the semiconductor structure 109 (FIG. 1A) relative to the first patterned masking lines 111 without removing portions of the insulative structure 108. Accordingly, lower boundaries (e.g., bottoms) of the y-axis trenches 112, as defined by upper surfaces 115 of the insulative structure 108, may be substantially planar.

With reference to FIG. 1C, a first dielectric liner material 116 may be formed in the y-axis trenches 112 and over the semiconductor projections 113 of the memory array structure 102. The first dielectric liner material 116 is formed over and along the semiconductor side surfaces 114 (FIG. 1B) of the semiconductor projections 113 and the upper surfaces 115 (FIG. 1B) of the insulative structure 108. Within the y-axis trenches 112, the first dielectric liner material 116 may include side portions 117 on the semiconductor side surfaces 114 of the semiconductor projections 113, and, optionally, bottom portions 118 on or over the upper surfaces 115 (FIG. 1B) of the insulative structure 108. Within an individual y-axis trench 112, the bottom portion 118 of the first dielectric liner material 116 may be integral and continuous with the side portions 117 of the first dielectric liner material 116. In some embodiments, upper surfaces of the bottom portions 118 of the first dielectric liner material 116 are vertically offset from (e.g., are vertically below) interfaces between the first doped regions 104 and the undoped regions 106 of the individual semiconductor projections 113.

The first dielectric liner material 116 may be formed of and include an insulative material. In some embodiments, the first dielectric liner material 116 is formed of and includes silicon dioxide. In some embodiments, the first dielectric liner material 116 is formed (e.g., conformally deposited) inside and outside of the y-axis trenches 112 and portions of the first dielectric liner material 116 outside of the y-axis trenches 112 (e.g., on upper surfaces of the first mask material 110) remain. In additional embodiments, the first dielectric liner material 116 is formed (e.g., conformally deposited) inside and outside of the y-axis trenches 112 and then portions of the first dielectric liner material 116 are removed (e.g., by way of CMP) while additional portions of the first dielectric liner material 116 within the y-axis trenches 112 are maintained. The side portions 117 and the bottom portions 118 of the first dielectric liner material 116 may have a thickness within a range of from about 3 nm to about 7 nm (e.g., about 5 nm).

Referring still to FIG. 1C, subsequent to forming the first dielectric liner material 116, an isolation material 119 may be formed within the y-axis trenches 112. For instance, the y-axis trenches 112 may be filled with the isolation material 119. In some embodiments, the isolation material 119 is formed of and includes a dielectric oxide material, such as SiOₓ (e.g., SiO₂). The isolation material 119 may be substantially homogeneous, or the isolation material 119 may be heterogeneous. The isolation material 119 may, for example, be formed of and include a stack of at least two different dielectric materials. The isolation material 119 may be formed (e.g., deposited) via and of the manners described herein.

Referring next to FIG. 1D, additional trenches 120 may be formed to extend vertically into the first assembly 103 and the semiconductor structure 109 of the memory array structure 102. The additional trenches 120 may extend horizontally in parallel in the X-direction (e.g., a second direction) perpendicular to the Y-direction and may be referred to herein as “x-axis trenches 120.”

In some embodiments, the x-axis trenches 120 are formed using an etching process (e.g., an anisotropic etching process) that removes exposed portions of the isolation material 119, the first dielectric liner material 116, the first mask material 110, and the semiconductor projections 113. Furthermore, the x-axis trenches 120 may be formed to terminate (e.g., have lower boundaries) within the isolation material 119 and portions of the first dielectric liner material 116 lining semiconductor side surfaces 114 of the semiconductor projections 113. In other words, portions of the isolation material 119, portions of the first dielectric liner material 116 lining semiconductor side surfaces 114 of the semiconductor projections 113, and the bottom portions 118 of the first dielectric liner material 116 overlying the insulative structure 108 may remain between the lower boundaries of the x-axis trenches 120 and the insulative structure 108. Accordingly, lower boundaries (e.g., bottoms) of the x-axis trenches 120 may be defined by upper surfaces of the isolation material 119 and the first dielectric liner material 116. In some embodiments, remaining portions of the semiconductor projections 113 within the x-axis trenches 120 may be subjected to one or more further etching processes to remove the remaining portions of the semiconductor projections 113 within the x-axis trenches 120 such that the upper surface of the insulative structure 108 is exposed in portions of the x-axis trenches 120 (e.g., horizontal areas immediately neighboring the semiconductor projections 113 in y-directions). As result, semiconductor pillars may be formed from the semiconductor projections 113, and the semiconductor pillars may be distinct and discrete from each other.

In one or more embodiments, some of the x-axis trenches 120 have larger widths in the Y-direction than other x-axis trenches 120. The x-axis trenches 120 having larger widths may be referred to as “wide x-axis trenches 121” hereinafter, and the x-axis trenches 120 having smaller widths may be referred to as “thin x-axis trenches 122” hereinafter. Furthermore, in some embodiments, each of the wide x-axis trenches 121 may be formed in between two thin x-axis trenches 122.

Referring to FIG. 1E, the x-axis trenches 120 may be partially filled within a spacer material 123. In one or more embodiments, the spacer material 123 is deposited within the x-axis trenches 120 through a spin-on coating process. For instance, the spacer material 123 may include a spin-on dielectric. Furthermore, subsequent to the spin-on coating process, the spacer material 123 may be recessed (e.g., removed through an etching process (dry or wet etching process)) to leave only portions of the spacer material 123 at the bottoms of the x-axis trenches 120.

In some embodiments, the spacer material 123 is formed of and includes a dielectric oxide material, such as SiOₓ (e.g., SiO₂). The spacer material 123 may be substantially homogeneous, or the spacer material 123 may be heterogeneous. The spacer material 123 may, for example, be formed of and include a stack of at least two different dielectric materials.

The degree to which the spacer material 123 is recessed may serve to position the later-formed gate electrodes (i.e., word lines) a desired distance from the insulative structure 108 and a boundary of the first doped region 104 and the undoped region 106 of the semiconductor projections 113. For instance, the remaining portion of the spacer material 123 may space the later-formed gate electrodes from the insulative structure 108 and the boundary of the first doped region 104 and the undoped region 106 of the semiconductor projections 113 by desired distances, and as a result, may space the later-formed gate electrodes from later-formed contacts and/or digit lines (discussed below). For example, the thickness of the spacer material 123 may at least partially determine a distance between the later-formed gate electrodes and a digit line junction. The remaining portion of the spacer material 123 may exhibit a thickness within a range of about 30 nm and about 60 nm. For instance, the spacer material 123 may be etched to have a thickness of about 45 nm.

With reference to FIG. 1F, a second dielectric liner material 124 (i.e., a gate dielectric material) may be formed in the x-axis trenches 120, over the semiconductor projections 113 (i.e., pillars), over the isolation material 119, over the first dielectric liner material 116, and over the spacer material 123 of the first assembly 103 of the memory array structure 102. The second dielectric liner material 124 may also be referred to as a gate dielectric material. The second dielectric liner material 124 is formed over and along the semiconductor side surfaces 114 (FIG. 1B) of the semiconductor projections 113 (i.e., pillars), exposed surfaces of the first dielectric liner material 116, upper surfaces of the spacer material 123, and exposed surfaces of the isolation material 119.

The second dielectric liner material 124 (i.e., gate dielectric material) may be formed of and include insulative material. In some embodiments, the second dielectric liner material 124 is formed of and includes silicon dioxide. In one or more embodiments, the second dielectric liner material 124 includes a material with a relatively high dielectric constant (k) (i.e., a high-k material). In some embodiments, the second dielectric liner material 124 is formed (e.g., conformally deposited) inside and outside of the x-axis trenches 120. The second dielectric liner material 124 may have a thickness within a range of from about 4 nm to about 6 nm (e.g., about 5 nm).

Referring still to FIG. 1F, word line structures 125 (e.g., access lines, gate electrodes, gate metal) may be formed on the second dielectric liner material 124 and within the x-axis trenches 120. The word line structures 125 may include any of the conductive materials described herein.

In one or more embodiments, the word line structures 125 are formed by at least partially filling the x-axis trenches 120 with a gate electrode material, and subsequently removing one or more portions of the gate electrode material. In some embodiments, the gate electrode material within the wide x-axis trenches 121 are recessed differently than the gate electrode material within the thin x-axis trenches 122.

As non-limiting examples, within the wide x-axis trenches 121, subsequent to depositing the gate electrode material within the x-axis trenches 120, an entirety of the gate electrode material may be recessed down to a desired upper boundary of the word line structures 125, and a center portion of the gate electrode material may be further recessed (e.g., removed) to form first recesses 126 extending vertically through the remaining gate electrode material and to the second dielectric liner material 124. As a result, two word line structures 125 separated by a respective first recess 126 may be formed within each of the wide x-axis trenches 121. Additionally, within the thin x-axis trenches 122, an entirety of the gate electrode material may be recessed down to a desired upper boundary of the word line structures 125, and the remaining gate electrode material forms a given word line structure 125.

In view of the foregoing, in some embodiments, the gate electrode material in both the wide x-axis trenches 121 and the thin x-axis trenches 122 are recessed down to a desired upper boundary of the word line structures 125 during a first etching process; and the first recesses 126 are formed within remaining gate electrode material within the wide x-axis trenches 121 in a subsequent, second etching process.

The gate electrode material may be formed (e.g., deposited) through any of the manners described herein. Additionally, recessing the gate electrode material and forming the first recesses 126 in the gate electrode material may be done by conventional techniques, such as by a directional, selective etch process (e.g., an anisotropic etch process, such as an anisotropic dry or wet etch process) that removes the gate electrode material without significantly removing other exposed materials (e.g., the second dielectric liner material 124) of the first assembly 103.

The first recesses 126 may be formed to a desired width (e.g., horizonal dimension) in the Y-direction such that portions of the gate electrode material (i.e., the word line structures 125) remain adjacent to the second dielectric liner material 124 in the Y-direction. In other words, the width of the first recesses 126 may be selected to result in a desired width of the word line structures 125 (i.e., gate electrodes) formed from the gate electrode material in the Y-direction.

Referring to FIG. 1G, the x-axis trenches 120, including the first recesses 126 between the word line structures 125 within the wide x-axis trenches 121, may be filled with a first insulative material 127. The first insulative material 127 may be a spin-on dielectric material and may be formed by a spin coating process. Moreover, the first insulative material 127 may include any of the dielectric materials described herein. The first insulative material 127 may optionally be subjected to an annealing process.

Additionally, the first mask material 110 and any of the first dielectric liner material 116, the second dielectric liner material 124, and the first insulative material 127 above an upper vertical boundary of the second doped region 105 of the semiconductor projections 113 may be removed. For example, the first mask material 110 and any of the first dielectric liner material 116, the second dielectric liner material 124, and the first insulative material 127 above an upper vertical boundary of the second doped region 105 of the semiconductor projections 113 may be removed by way of a CMP process. In some embodiments, some of the second doped regions 105 of the semiconductor projections 113 may also be removed by way of the removal process. As a result, a distance between the word line structures 125 and an upper boundary of the second doped region 105 may be selected. Due to the removal of the first mask material 110 and any of the first dielectric liner material 116, the second dielectric liner material 124, and the first insulative material 127 above an upper vertical boundary (or chosen upper vertical boundary) of the second doped regions 105 of the semiconductor projections 113, portions of the second doped region 105, the first dielectric liner material 116, the second dielectric liner material 124, and the first insulative material 127 are exposed on a current upper surface of the first assembly 103.

FIG. 1GA is a cross-sectional view of the microelectronic device 100 along the line A-A. Referring to FIG. 1G and FIG. 1GA together, merged word line structures 125 within the thin x-axis trenches 122 may form a shield gate 172 or back gate that shields word line structures 125 from cross-interference between word line structures 125 within the wide x-axis trenches 121. For example, the shield gates 172 may control electrical field interference between the access devices 134. In some embodiments, the shield gates 172 are formed from tungsten or another conductive material. In one or more embodiments, the shield gates 172 are formed from a semiconductor material (e.g., polysilicon). Furthermore, the shield gates 172 may be operably connected to a respective voltage supply at an edge of the array.

With reference to FIG. 1H, a second mask material may be formed over exposed upper surfaces of second doped regions 105, the first dielectric liner material 116, the second dielectric liner material 124, and the first insulative material 127 (i.e., a current upper surface of the first assembly 103), and the second mask material may be patterned to form second patterned masking lines horizontally extending in parallel with one another in the X-direction. The second mask material may be patterned into the second patterned masking lines utilizing any suitable methodology. For instance, in some embodiments, a photoresist material is formed on or over the second mask material, is patterned (e.g., photo exposed and developed), and then openings formed in the patterned photoresist material are extended into the second mask material to form the second patterned masking lines. The second patterned masking lines may be removed during subsequent processing stages or may remain in a final device formed through the methods of the disclosure. The second mask material may be formed of and include a dielectric material, such as a dielectric nitride material (e.g., silicide nitride).

The second patterned masking lines may be employed to form additional x-axis trenches 130 extending vertically into the first assembly 103. The additional x-axis trenches 130 may extend horizontally in parallel in the X-direction and may be at least substantially vertically aligned (i.e., aligned in a vertical direction) with the previously formed x-axis trenches (FIG. 1E). The additional x-axis trenches 130 may extend vertically into the first assembly 103 to an elevation (e.g., vertical level) between an upper boundary and a lower boundary of the second doped regions 105 of the semiconductor projections 113. Forming the additional x-axis trenches 130 into the second doped regions 105 of the semiconductor projections 113 (i.e., pillars) defines raised portions of second doped regions 105, which can serve as contact structures 131 (e.g., access pathways) to the semiconductor projections 113 (e.g., the first doped regions 104, the undoped regions 106, and the second doped regions 105 of the semiconductor projections 113) for later formed storage node elements (e.g., capacitors). Furthermore, the additional x-axis trenches 130 may form a part of a pattern for a later-formed redistribution material (RDM) tier (also referred to as “redistribution layer” (RDL) tier).

In some embodiments, the additional x-axis trenches 130 are formed using an etching process (e.g., an anisotropic etching process) that removes exposed portions of the first assembly 103. Furthermore, the additional x-axis trenches 130 may be formed to terminate (e.g., have lower boundaries) between upper and lower boundaries of the second doped region 105 of the semiconductor projections 113 of the first assembly 103.

As shown in FIG. 1I, the additional x-axis trenches 130 may be filled with a second insulative material 132. The second insulative material 132 may be a spin-on dielectric material and may be formed by a spin coating process. Moreover, the second insulative material 132 may include any of the dielectric materials described herein. For instance, the second insulative material 132 may include a same dielectric material as the first insulative material 127. The second insulative material 132 may optionally be subjected to an annealing process.

Additionally, the second mask material and any of the second insulative material 132 above an upper vertical boundary of the second doped region 105 of the semiconductor projections 113 (e.g., the contact structures 131) may be removed. For example, the second mask material and any of the second insulative material 132 above an upper vertical boundary of the second doped region 105 of the semiconductor projections 113 (e.g., the contact structures 131) may be removed by way of a CMP process.

Still referring to FIG. 1I, the semiconductor projections 113 may form at least portions of vertical access devices 134 (e.g., vertical transistors, access transistors). An individual vertical access device 134 may include a channel region comprising the undoped region 106 of an individual semiconductor projection 113 (i.e., pillar), a drain region comprising the first doped region 104 of the semiconductor projection 113 (i.e., pillar), and a source region comprising the second doped region 105 of the semiconductor projection 113 (i.e., pillar). In addition, the vertical access devices 134 may include a gate electrode (e.g., a word line structure 125) and a gate dielectric material (e.g., the second dielectric liner material 124). A given word line structure 125 may be utilized as a gate electrode for multiple vertical access devices 134.

Referring to FIG. 1J, a third mask material 135 may be formed over (e.g., overlying) exposed surfaces of second doped region 105, the first dielectric liner material 116, the second dielectric liner material 124, the first insulative material 127, and the second insulative material 132. For instance, a third mask material 135 may be formed over a current upper surface of the first assembly 103. Additionally, a sacrificial material 136 may be formed over the third mask material 135. In some embodiments, the third mask material 135 is formed of and includes a dielectric nitride material (e.g., silicon nitride), and the sacrificial material 136 is formed of and includes an oxide material (e.g., silicon dioxide). In one or more embodiments, the third mask material 135 and the sacrificial material 136 may each have etched selectively relative at least to the other materials of the first assembly 103.

Furthermore, the sacrificial material 136 and the third mask material 135 may be patterned to form openings 137 extending vertically through the sacrificial material 136 and the third mask material 135. The openings 137 may expose the contact structures 131 of the semiconductor projections 113 (e.g., the second doped regions 105 of the semiconductor projections 113). The openings 137 may horizontally overlap and vertically extend to the contact structures 131 of the semiconductor projections 113. Furthermore, each opening 137 may be vertically aligned (e.g., in vertical direction) with at least a portion of a respective contact structure 131 of the semiconductor projections 113.

The sacrificial material 136 and the third mask material 135 may be patterned to form the openings 137 utilizing any suitable methodology. For instance, in some embodiments, a photoresist material is formed on or over the sacrificial material 136, is patterned (e.g., photo exposed and developed), and then openings formed in the patterned photoresist material are extended into the sacrificial material 136 and the third mask material 135 to form the openings 137.

With reference to FIG. 1K and FIG. 1KA, which is a cross-sectional view of the microelectronic device 100 along the line B-B, a remaining portion of the third mask material 135 and the RDM structures 138 may form a redistribution layer tier (RDL tier 139) of the first assembly 103.

The RDM structures 138 may, for example, facilitate a horizontal arrangement (e.g., a hexagonal close packed arrangement) of storage node devices (e.g., capacitors) (described below) that is different than a horizontal arrangement of the contact structures 131 of the semiconductor projections 113, while still electrically connecting the contact structures 131 to the storage node devices. The RDM structures 138 may be formed of and include one or more of W, Ru, Mo, and TiN_{y}.

As shown in FIG. 1L and FIG. 1M, a multi-storage node structure 140 including multiple storage node devices 141 (e.g., capacitors) may be formed on or over the RDL tier 139 and the RDM structures 138 to form a second assembly 142, the second assembly 142 including the first assembly 103 and the multi-storage node structure 140. The storage node devices 141 may be in electrical contact with the RDM structures 138, and, hence, with the contact structures 131 of the semiconductor projections 113 (e.g., the access devices 134). The storage node devices 141 may be coupled to the semiconductor projections 113 by way of the contact structures 131 and the RDM structures 138 to form memory cells 144 (e.g., DRAM cells).

Each memory cell 144 may individually include one of the access devices 134, one of the storage node devices 141, one of the contact structures 131, and one of the RDM structures 138. The storage node devices 141 may individually be formed and configured to store a charge representative of a programmable logic state of the memory cell 144 including the storage node device 141.

In some embodiments, the storage node devices 141 include capacitors. During use and operation, a charged capacitor may represent a first logic state, such as a logic 1; and an uncharged capacitor may represent a second logic state, such as a logic 0. Each of the storage node devices 141 may, for example, be formed to include a first electrode 145 (e.g., a bottom electrode), a second electrode 146 (e.g., a top electrode), and a first dielectric material 147 between the first electrode 145 and the second electrode 146. For instance, each of the storage node devices 141 may include a metal-insulator-metal (MIM) capacitor. As another example, each of the storage node devices 141 may include a metal-insulator-semiconductor (MIS) capacitor. The collection of memory cells 144 may form a memory array.

The multi-storage node structure 140 may further include a conductive material 148 formed between neighboring storage node devices 141. The conductive material 148 may substantially cover and surround the storage node devices 141. The second electrode 146 of the storage node devices 141 may be operatively positioned (e.g., embedded) within the conductive material 148. The conductive material 148 may include any of the conductive materials described herein. For instance, the conductive material 148 may include polysilicon or conductively doped silicon germanium (SiGe).

Referring still to FIG. 1L and FIG. 1M together, a cell plate 149 may be formed on and over the multi-storage node structure 140 of the second assembly 142. For instance, the cell plate 149 may be formed on and over an upper surface of the conductive material 148. The cell plate 149 may include any of the conductive materials described herein. For instance, the cell plate 149 may include a tungsten (W).

Referring now to FIG. 1N, a first carrier structure 150 may be attached to the multi-storage node structure 140 of the second assembly 142. The first carrier structure 150 may include a second base structure 152 and a fourth insulative material 153 on and overlying the second base structure 152.

In some embodiments, the fourth insulative material 153 is formed of and includes a dielectric oxide material, such as SiOₓ (e.g., SiO₂). The fourth insulative material 153 may be substantially homogeneous, or the fourth insulative material 153 may be heterogeneous.

The second base structure 152 may include a base material or construction upon which additional features (e.g., materials, structures, devices) of the formed. In some embodiments, the second base structure 152 comprises a wafer. The second base structure 152 may be formed of and include one or more of semiconductor material (e.g., one or more of a silicon material, such monocrystalline silicon or polycrystalline silicon (also referred to herein as “polysilicon”); silicon-germanium; germanium; gallium arsenide; a gallium nitride; gallium phosphide; indium phosphide; indium gallium nitride; and aluminum gallium nitride), a base semiconductor material on a supporting structure, glass material (e.g., one or more of BSP, PSG, FSG, BPSG, aluminosilicate glass, an alkaline earth boro-aluminosilicate glass, quartz, titania silicate glass, and soda-lime glass), and ceramic material (e.g., one or more of p-AlN, SOPAN, AlN, aluminum oxide (e.g., sapphire; α-Al₂O₃), and silicon carbide). By way of non-limiting example, the second base structure 152 may comprise a semiconductor wafer (e.g., a silicon wafer), a glass wafer, or a ceramic wafer. The second base structure 152 may include one or more layers, structures, and/or regions formed therein and/or thereon.

To attach the first carrier structure 150 to the multi-storage node structure 140, the fourth insulative material 153 of the first carrier structure 150 may be provided in physical contact with at least an insulative material of the multi-storage node structure 140, and the fourth insulative material 153 and the insulative material of the multi-storage node structure 140 may be exposed to annealing conditions to form bonds (e.g., oxide-to-oxide bonds) between the fourth insulative material 153 and the insulative material of the multi-storage node structure 140. By way of non-limiting example, the fourth insulative material 153 and the insulative material of the multi-storage node structure 140 may be exposed to a temperature greater than or equal to about 400° C. (e.g., within a range of from about 300° C. to about 500° C., greater than about 500° C.) to form oxide-to-oxide bonds between the fourth insulative material 153 and the insulative material of the multi-storage node structure 140. In some embodiments, the fourth insulative material 153 and the insulative material of the multi-storage node structure 140 are exposed to at least one temperature greater than about 800° C. to form oxide-to-oxide bonds between the fourth insulative material 153 and the insulative material of the multi-storage node structure 140.

Referring now to FIG. 1O and FIG. 1P, the second assembly 142 may be vertically inverted such that the access devices 134 vertically overlay the multi-storage node structure 140, and then at least one thinning process (e.g., a CMP process; an etching process, such as a conventional dry etching process or a wet etching process) may be performed on the first base structure 107 and the insulative structure 108 of the first assembly 103 to remove the first base structure 107 and the insulative structure 108. Furthermore, the thinning process may be stopped at upper surfaces (following vertical inversion) of the first dielectric liner material 116 and the first doped regions 104 of the semiconductor projections 113. For instance, the thinning process (e.g., the removal process) may be stopped at an intended digit line junction.

Referring to FIG. 1Q, digit line structures 154 (e.g., bit line structures, data line structures) may be formed on or over the semiconductor projections 113 of the first assembly 103. In particular, the digit line structures 154 are formed vertically on or over each of the semiconductor projections 113. The digit line structures 154 may be formed of and include a conductive material 156. The conductive material 156 may include one or more conductive materials. In some embodiments, the conductive material 156 includes tungsten, either alone or in combination with one or more conductive barrier materials (e.g., oxidation-resistant materials which protect the tungsten from oxidation in embodiments in which the tungsten may be exposed to oxygen).

The digit line structures 154 may be formed to any suitable dimensions (e.g., width, thickness). By way of example, the digit line structures 154 may individually be formed to a width, in the X-direction, equal to about the width of an individual semiconductor projections 113 (e.g., in a range of from about 10 nm to about 30 nm). The digit line structures 154 may be formed to any suitable pitch. The digit line structures 154 may be spaced apart from one another by a distance equal to about the distance between the semiconductor projections 113 horizontally neighboring one another in the X-direction.

The digit line structures 154 may be formed using any suitable processing. For instance, the conductive material 156 may be formed on or over the upper surface of the second assembly 142 (e.g., upper surfaces of the first dielectric liner material 116 and the first doped regions 104 of the semiconductor projections 113), and a fourth mask material 158 may be formed over an upper surface of the conductive material 156, and the fourth mask material 158 may be patterned to form fourth patterned masking lines 159 horizontally extending in parallel with one another in the Y-direction. The fourth mask material 158 may be patterned into the fourth patterned masking lines 159 utilizing any suitable methodology. For instance, in some embodiments, a photoresist material is formed on or over the fourth mask material 158, is patterned (e.g., photo exposed and developed), and then openings formed in the patterned photoresist material are extended into the fourth mask material 158 to form the fourth patterned masking lines 159.

The fourth patterned masking lines 159 may be employed to form additional y-axis trenches 160 extending vertically through the conductive material 156 of the memory array structure 102. The additional y-axis trenches 160 may extend horizontally in parallel in the Y-direction. The additional y-axis trenches 160 may have any suitable dimensions. For instance, the additional y-axis trenches 160 may have a width, in the X-direction, at least substantially equal to about the width of an individual space between neighboring semiconductor projections 113.

In some embodiments, the additional y-axis trenches 160 are formed using an etching process (e.g., an anisotropic etching process) that selectively removes exposed portions of the conductive materials 156 relative to the fourth patterned masking lines 159 without removing portions of the first dielectric liner material 116. Accordingly, lower boundaries (e.g., bottoms) of the additional y-axis trenches 160, as defined by upper surfaces of the first dielectric liner material 116, may be substantially planar.

Referring next to FIG. 1R, a third dielectric liner material 162 may be formed within the additional y-axis trenches 160 and over the digit line structures 154 and the fourth patterned masking lines 159 of the memory array structure 102. For instance, the third dielectric liner material 162 may be formed (e.g., conformally deposited) inside the additional x-axis trenches 130 and over the digit line structures 154 and fourth patterned masking lines 159. In some embodiments, the third dielectric liner material 162 may not entirely fill the additional x-axis trenches 130. For instance, second recesses 163 may remain between portions the third dielectric liner material 162 deposited on the sidewalls of the digit line structures 154 and the fourth patterned masking lines 159 of the memory array structure 102.

Within the additional y-axis trenches 160, the third dielectric liner material 162 may include side portions on the side surfaces of the digit line structures 154 and the fourth patterned masking lines 159, and, optionally, bottom portions on or over the upper surfaces of the first dielectric liner material 116.

The third dielectric liner material 162 may be formed of and include insulative material. In some embodiments, the third dielectric liner material 162 may be formed of and includes silicon dioxide. The third dielectric liner material 162 may have a thickness within a range of from about 3 nm to about 7 nm (e.g., about 5 nm).

Referring still to FIG. 1R, a shield structure 164 may be formed over the third dielectric liner material 162. For instance, the shield structure 164 may be deposited (e.g., conformally deposited) within the second recesses 163 and over the third dielectric liner material 162. The shield structure 164 may at least substantially entirely fill the second recesses 163 and cover an upper surface of the third dielectric liner material 162. As a result, in some embodiments, the shield structure 164 include projections 170 extending vertically downward between horizontally neighboring digit line structures 154. Moreover, because the shield structure 164 at least substantially entirely fills the second recesses 163, the shield structure 164 may extend vertically in-between neighboring digit line structures 154. Put another way, portions of the shield structure may be horizontally interposed between neighboring digit line structures 154 of the memory array structure 102.

The shield structure 164 (e.g., upper shielding plate, top shielding plate) may be configured and positioned to shield (e.g., protect) features (e.g., structures, materials, devices, digit lines) within the memory cells 144 of the memory array structure 102 from undesirable electrical interference (e.g., electromagnetic interference (EMI)).

In some embodiments, the third dielectric liner material 162 may at least substantially fill the additional y-axis trenches 160, and the shield structure 164 may be formed over a substantially uniform or continuous upper surface of the third dielectric liner material 162. As a result, in some embodiments, the shield structure 164 may not include the projections 170 extending vertically downward between horizontally neighboring digit line structures 154 and, rather, may include a generally flat structure.

In view of the foregoing, the shield structure 164 may vertically overlie the digit line structures 154, which vertically overlie the access devices 134 of the memory cells 144. Accordingly, the access devices 134 may be vertically interposed between the digit line structures 154 and the multi-storage node structure 140.

The shield structure 164 may be formed of and include conductive material. In some embodiments, the shield structure 164 is formed of and includes metallic material, such as one or more of at least one metal, at least one alloy, and at least one conductive metal-containing material (e.g., a conductive metal nitride, a conductive metal silicide, a conductive metal carbide, a conductive metal oxide). By way of non-limiting example, the shield structure 164 may be formed of and include tungsten (W). The shield structure 164 may be substantially homogeneous, or the shield structure 164 may be heterogeneous. If the shield structure 164 is heterogeneous, amounts of one or more elements included in the shield structure 164 may vary stepwise (e.g., change abruptly), or may vary continuously (e.g., change progressively, such as linearly, parabolically) throughout different portions of the shield structure 164. The shield structure 164 may, for example, be formed of and include a stack of at least two different conductive materials.

Referring next to FIG. 1S, a fifth insulative material 166 may be formed over and on the shield structure 164 of the second assembly 142. In some embodiments, the fifth insulative material 166 is formed (e.g., deposited) through any of the manners described herein. Furthermore, the fifth insulative material 166 may be formed to have an at least substantially planar upper surface 168. In one or more embodiments, the fifth insulative material 166 is formed of and includes a dielectric oxide material, such as SiOₓ (e.g., SiO₂). The fifth insulative material 166 may be substantially homogeneous, or the fifth insulative material 166 may be heterogeneous. As is discussed in greater detail below, in some embodiments, the first insulative material 127 may be utilized to bond the memory array structure 102 to another structure (e.g., a second microelectronic device structure) through dielectric-to-dielectric bonding, such as an oxide-to-oxide bonding.

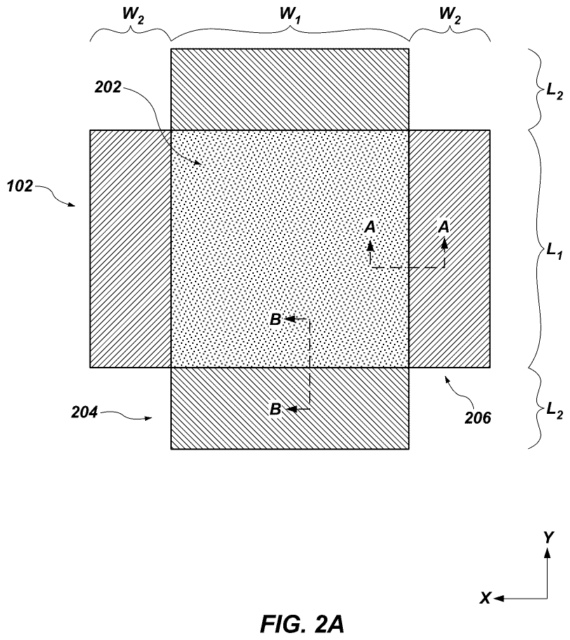

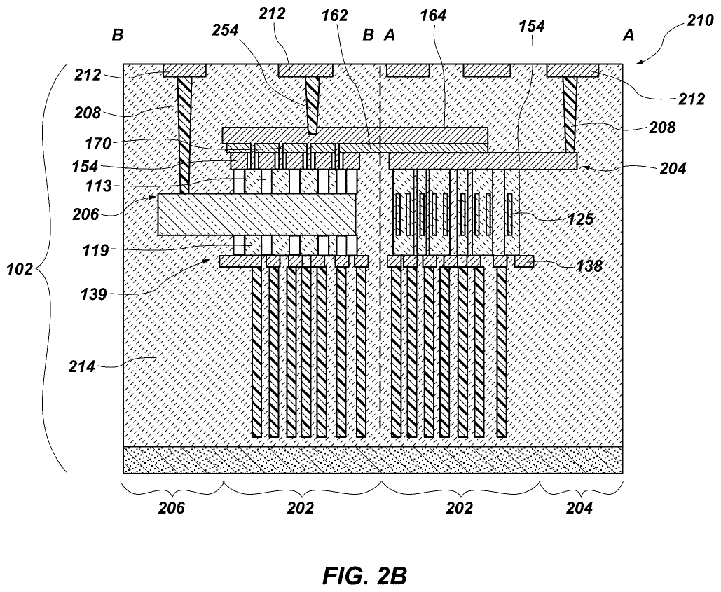

FIG. 2A is a simplified, partial plan view of the memory array structure 102 at a processing stage of the method of forming the microelectronic device 100 following the processing stages described above in regard to FIG. 1A through FIG. 1S. The memory array structure 102 may be formed to include an array region 202, digit line exit regions 204 (also referred to as “digit line (DL) contact socket regions”) horizontally neighboring the array region 202 in the X-direction, and word line exit regions 206 (also referred to as “word line (WL) contact socket regions”) horizontally neighboring the array region 202 in an Y-direction orthogonal to the X-direction. The array region 202, the digit line exit regions 204, and the word line exit regions 206 are each described in further detail below.

Referring to FIG. 2A, the array region 202 of the memory array structure 102 is a horizontal area of the memory array structure 102 including an array of the memory cells 144 (FIG. 1O) (e.g., an array of DRAM cells) described above. The memory array structure 102 may include a desired quantity and distribution of array regions 202. For clarity and ease of understanding of the drawings and related description, FIG. 2A depicts the memory array structure 102 as including one (1) array region 202, but the memory array structure 102 may be formed to include multiple (e.g., more than one (1)) array regions 202 horizontally offset (e.g., in one or more of the X-direction and the Y-direction) from one another. For example, the memory array structure 102 may include greater than or equal to four (4) array regions 202, greater than or equal to eight (8) array regions 202, greater than or equal to sixteen (16) array regions 202, greater than or equal to thirty-two (32) array regions 202, greater than or equal to sixty-four (64) array regions 202, greater than or equal to one hundred twenty-eight (128) array regions 202, greater than or equal to two hundred fifty-six (256) array regions 202, greater than or equal to five hundred twelve (512) array regions 202, or greater than or equal to one thousand twenty-four (1024) array regions 202.

As shown in FIG. 2A, the array region 202 of the memory array structure 102 may have a first width W₁ in the Y-direction and a first length L₁ in the X-direction orthogonal to the Y-direction. In some embodiments, the first width W₁ is substantially equal to the first length L₁. In additional embodiments, the first width W₁ is different than (e.g., greater than, less than) the first length L₁.

The digit line exit regions 204 of the memory array structure 102 may include horizontal areas of the memory array structure 102 configured include portions of digit line structures 154 (FIG. 1R) (e.g., bit line structures, data line structures) within horizontal boundaries thereof. For an individual digit line exit region 204, at least some digit line structures 154 (FIG. 1R) operatively associated with the array region 202 horizontally neighboring the digit line exit region 204 in the X-direction may have portions within the horizontal area of the digit line exit region 204. In addition, the digit line exit region 204 may also be configured to include conductive contact structures and conductive routing structures within the horizontal areas thereof that are operatively associated with the digit line structures 154 (FIG. 1R). As described in further detail below, some of the conductive contact structures within the digit line exit regions 204 may couple the digit line structures to control logic circuitry of control logic devices (e.g., sense amplifier (SA) devices) to subsequently be provided vertically over the memory array structure 102. In some embodiments, the digit line exit regions 204 respectively horizontally extend in the Y-direction. An individual array region 202 may be horizontally interposed between horizontally neighboring digit line exit regions 204 in the X-direction.

As shown in FIG. 2A, the digit line exit regions 204 of the memory array structure 102 may respectively have the first width W₁ in the Y-direction and a second length L₂ in the X-direction orthogonal to the Y-direction. The second length L₂ of an individual digit line exit region 204 is smaller than the first width W₁ of the digit line exit region 204. In addition, the second length L₂ of the digit line exit region 204 is smaller than the first length L₁ of an individual array region 202 of the memory array structure 102.

The word line exit regions 206 of the memory array structure 102 may include additional horizontal areas of the memory array structure 102 including portions of the word line structures 125 (FIG. 1I) (e.g., gate electrodes, access line structures) within horizontal boundaries thereof. For an individual word line exit region 206, at least some word line structures 125 (FIG. 1I) operatively associated with the array region 202 horizontally neighboring the word line exit region 206 in the Y-direction may have portions within the horizontal area of the word line exit region 206. In addition, the word line exit regions 206 may also include additional conductive contact structures and additional conductive routing structures within the horizontal areas thereof that are operatively associated with the word line structures 125 (FIG. 1I). As described in further detail below, some of the additional conductive contact structures within the word line exit regions 206 may couple the word line structures 125 (FIG. 1I) to additional control logic circuitry of additional control logic devices (e.g., sub word line driver (SWD) devices) to subsequently be provided vertically over the memory array structure 102. In some embodiments, the word line exit regions 206 respectively horizontally extend in the X-direction. An individual array region 202 may be horizontally interposed between horizontally neighboring word line exit regions 206 in the Y-direction.

As shown in FIG. 2A, the word line exit regions 206 of the memory array structure 102 may respectively have a second width W₂ in the Y-direction and the first length L₁ in the X-direction orthogonal to the Y-direction. The second width W₂ of an individual word line exit region 206 is smaller than the first length L₁ of the word line exit region 206. In addition, the second width W₂ of the word line exit region 206 is smaller than the first width W₁ of an individual array region 202 of the memory array structure 102.

FIG. 2B is a diagram showing different vertical cross-sectional views of the memory array structure 102 shown in FIG. 2A and taken about lines A-A and B-B of FIG. 2A. Referring to FIG. 2A and FIG. 2B together, the vertical cross section of the memory array structure 102 taken about line A-A is a view of a YZ-plane of a portion of the memory array structure 102 horizontally overlapping the array region 202 and one of the word line exit regions 206 of the memory array structure 102. The vertical cross section of the memory array structure 102 taken about line B-B is a view of an XZ-plane of an additional portion of the memory array structure 102 overlapping the array region 202 and one of the digit line exit regions 204 of the memory array structure 102.

Additionally, the different vertical cross-sectional views of FIG. 2B show the memory array structure 102 at a processing stage of the method of forming a microelectronic device 100 following the processing stages described above in regard to FIG. 1A through FIG. 1S. In particular, the method described above with reference to FIG. 1A through FIG. 1S may effectuate the formation of the memory array structure 102 (e.g., a memory device, such as a DRAM device) of the microelectronic device including the features (e.g., regions, structures, materials, devices) described above. For clarity and ease of depiction, not every element of the memory array structure 102 is depicted within FIG. 2B; however, the memory array structure 102 may include any of the materials, structures, and elements (e.g., dielectric materials, dielectric liner materials, structures) of the memory array structure 102 described above in regard to FIG. 1A through FIG. 1S.

In addition to the features of the memory array structure 102 described above, the memory array structure 102 may also include interconnect structures 208 and at least one first routing tier 210 including first routing structures 212. The interconnect structures 208 and the first routing structures 212 may be formed subsequent to or during the method and process described above in regard to FIG. 1A through FIG. 1S. The individual interconnect structures 208 may be formed to contact (e.g., physically contact, electrically contact) one of the word line structures 125 or the digit line structures 154. The interconnect structures 208 may respectively be formed of and include conductive material. In some embodiments, the interconnect structures 208 are individually formed of and include one or more of W, Cu, Al, Ru, Mo, and TiN_{y}.

The first routing structures 212 may be formed to vertically overlie the interconnect structures 208. Some of the first routing structures 212 may be coupled to (e.g., in physical contact, electrical contact with) the interconnect structures 208 (and, hence, the word line structures 125, the digit line structures 154). The first routing structures 212 may respectively be formed of and include conductive material. In some embodiments, the first routing structures 212 are individually formed of and include one or more of W, Cu, Al, Ru, Mo, and TiN_{y}.

Additionally, shield contacts 254 may be formed subsequent to or during the method and process described above in regard to FIG. 1A through FIG. 1S. The shield contacts 254 may be formed to contact (e.g., physically contact, electrically contact) the shield structure 164. The shield contacts 254 may respectively be formed of and include conductive material. In some embodiments, the shield contacts 254 are individually formed of and include one or more of W, Cu, Al, Ru, Mo, and TiN_{y}. Additionally, the shield contacts 254 may extend vertically to one or more of the first routing structures 212. As a result, the shield contacts 254 may reach the shield structure 164 from a side of the shield structure 164 opposite the access devices 134 and multi-storage node structures 140 of the memory array structure 102 (e.g., from a top of the shield structure 164). In some embodiments, the shield contacts 254 may be utilized to apply a voltage bias to the shield structure 164 to control or enhance protection provided by the shield structure 164 from undesirable electrical interference (e.g., electromagnetic interference (EMI)).

Referring still to FIG. 2A and FIG. 2B, a sixth insulative material 214 may be formed on or over portions of at least the first carrier structure 150, the multi-storage node structure 140, the first assembly 103, the second assembly 142, the interconnect structures 208, and the first routing structures 212. In some embodiments, the sixth insulative material 214 is the fifth insulative material 166 (FIG. 1S) described above in regard to FIG. 1S. In other embodiments, the sixth insulative material 214 is an additional insulative material formed on or over the fifth insulative material 166 (FIG. 1S). In some embodiments, the sixth insulative material 214 is formed of and includes a dielectric oxide material, such as SiOₓ (e.g., SiO₂). The sixth insulative material 214 may be substantially homogeneous, or the sixth insulative material 214 may be heterogeneous. An upper surface of the sixth insulative material 214 may be formed to be substantially planar. In some embodiments, the upper surface of the sixth insulative material 214 is formed vertically overlie the upper surfaces of the uppermost ones of the first routing structures 212. In additional embodiments, the upper surface of the sixth insulative material 214 is formed to be substantially coplanar with upper surfaces of uppermost ones of the first routing structures 212.

As is discussed in greater detail below, the sixth insulative material 214 (which may be the fifth insulative material 166 (FIG. 1S)) may be utilized to bond the memory array structure 102 to another structure (e.g., a second microelectronic device structure) through a dielectric-to-dielectric bond, such as an oxide-to-oxide bond.

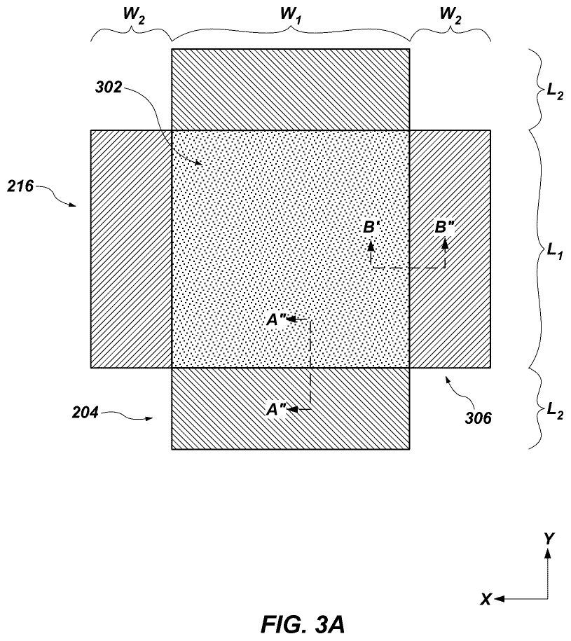

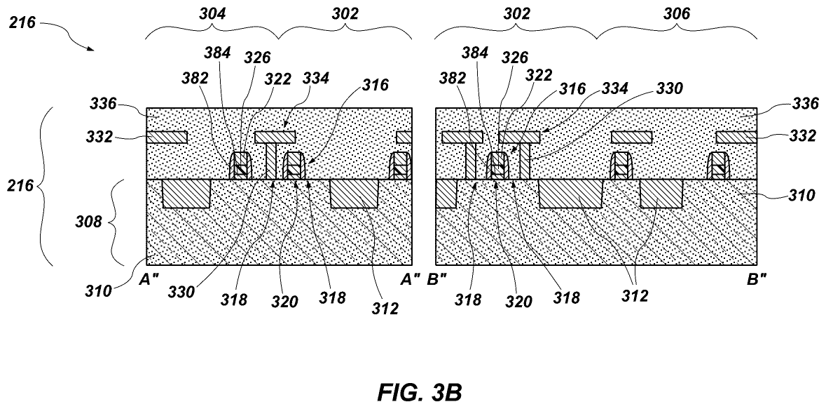

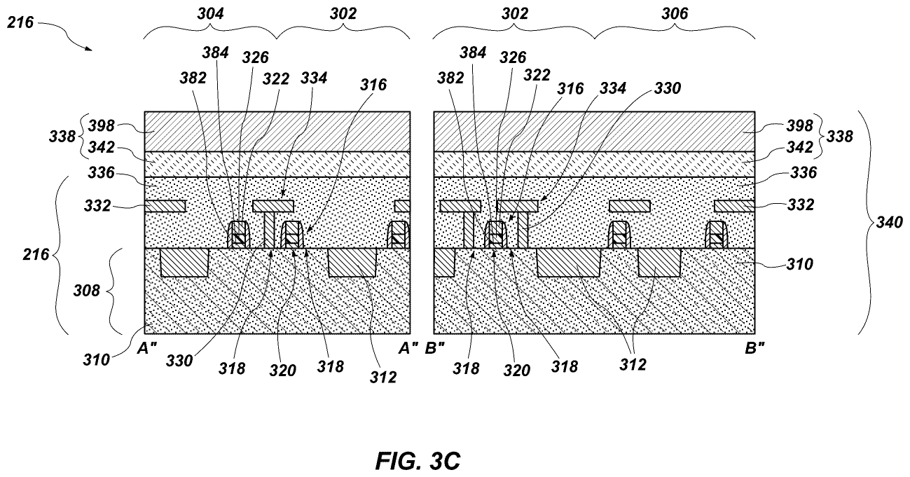

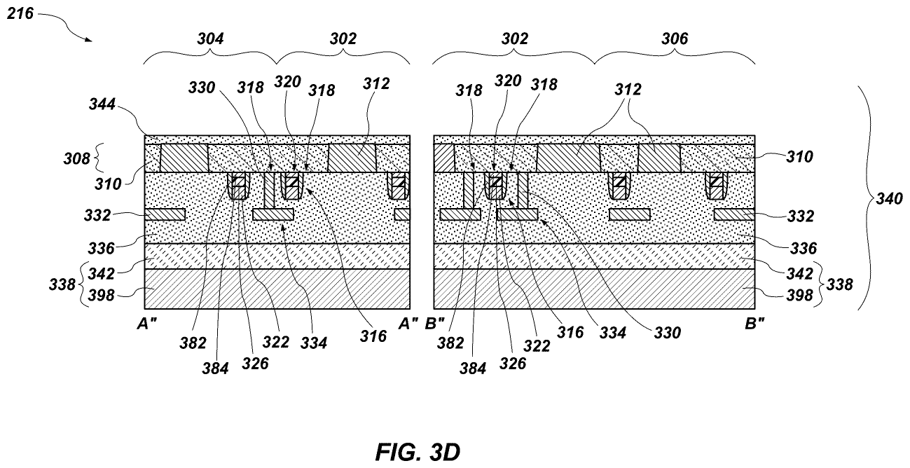

FIG. 3A is a simplified, partial plan view of a control circuitry structure 216 (e.g., a second wafer, a second die) at a processing stage of the method of forming the microelectronic device 100, in accordance with embodiments of the disclosure. The control circuitry structure 216 may be formed separate from memory array structure 102 (FIG. 1A through FIG. 1S) is configured to be attached (e.g., bonded) to the memory array structure 102, as described in further detail below.

As shown in FIG. 3A, the control circuitry structure 216 may be formed to include a control circuitry region 302, first peripheral regions 304 horizontally neighboring the control circuitry region 302 in a X-direction, and second peripheral regions 306 horizontally neighboring the control circuitry region 302 in a Y-direction orthogonal to the X-direction. The control circuitry region 302, the first peripheral regions 304, and the second peripheral regions 306 are each described in further detail below.

FIG. 3B is a diagram showing different vertical cross-sectional views of the control circuitry structure 216 shown in FIG. 3A, taken about lines A″-A″ and B″-B″ of FIG. 3A. The vertical cross section of the control circuitry structure 216 taken about line A″-A″ is a view of a XZ-plane of a portion of the control circuitry structure 216 horizontally overlapping the control circuitry region 302 and one of the first peripheral regions 304 of the control circuitry structure 216. The vertical cross section of the control circuitry structure 216 taken about line B″-B″ is a view of an YZ-plane of an additional portion of the control circuitry structure 216 overlapping the control circuitry region 302 and one of the second peripheral regions 306 of the control circuitry structure 216.

Referring again to FIG. 3A, the control circuitry region 302 of the control circuitry structure 216 includes control logic circuitry of the control circuitry structure 216 within a horizontal area thereof. The control logic circuitry of the control circuitry region 302 of the control circuitry structure 216 may be configured to be operatively associated with circuitry (e.g., memory cells 144 (FIG. 1L)) of the memory array structure 102 (FIG. 1L), as described in further detail below. In some embodiments, the control circuitry region 302 is configured to at least partially (e.g., substantially) horizontally overlap a respective array region 202 (FIG. 2B) of the memory array structure 102 (FIG. 2B) following subsequent attachment of the control circuitry structure 216 to the memory array structure 102 (FIG. 2B), as also described in further detail below.

For clarity and ease of understanding of the drawings and related description, FIG. 3A depicts the control circuitry structure 216 as including one (1) control circuitry region 302, but the control circuitry structure 216 may be formed to include multiple (e.g., more than one (1)) control circuitry regions 302 horizontally offset (e.g., in one or more of the X-direction and the Y-direction) from one another. For example, the control circuitry structure 216 may include greater than or equal to four (4) control circuitry regions 302, greater than or equal to eight (8) control circuitry regions 302, greater than or equal to sixteen (16) control circuitry regions 302, greater than or equal to thirty-two (32) control circuitry regions 302, greater than or equal to sixty-four (64) control circuitry regions 302, greater than or equal to one hundred twenty-eight (128) control circuitry regions 302, greater than or equal to two hundred fifty-six (256) control circuitry regions 302, greater than or equal to five hundred twelve (512) control circuitry regions 302, or greater than or equal to one thousand twenty-four (1024) control circuitry regions 302. In some embodiments, a quantity of the control circuitry regions 302 of the control circuitry structure 216 substantially equals a quantity of the array regions 202 (FIG. 2B) of the memory array structure 102 (FIG. 2B).

The first peripheral regions 304 of the control circuitry structure 216 respectively include additional circuitry (e.g., peripheral circuitry) of the control circuitry structure 216 within a horizontal area thereof. In some embodiments, the first peripheral regions 304 are configured to at least partially (e.g., substantially) horizontally overlap respective digit line exit regions 204 (FIG. 2B) of the memory array structure 102 (FIG. 2B) following subsequent attachment of the control circuitry structure 216 to the memory array structure 102, as described in further detail below. In some embodiments, a quantity of the first peripheral regions 304 of the control circuitry structure 216 substantially equals a quantity of the digit line exit regions 204 (FIG. 2B) of the memory array structure 102 (FIG. 2B). As shown in FIG. 3A, the first peripheral regions 304 may respectively horizontally extend in the Y-direction. An individual control circuitry region 302 of the control circuitry structure 216 may be horizontally interposed between horizontally neighboring first peripheral regions 304 of the control circuitry structure 216 in the X-direction.

The second peripheral regions 306 of the control circuitry structure 216 respectively include further circuitry (e.g., further peripheral circuitry) of the control circuitry structure 216 within a horizontal area thereof. In some embodiments, the second peripheral regions 306 are configured to at least partially (e.g., substantially) horizontally overlap respective word line exit regions 206 (FIG. 2B) of the memory array structure 102 (FIG. 2B) following subsequent attachment of the control circuitry structure 216 to the memory array structure 102, as described in further detail below. In some embodiments, a quantity of the second peripheral regions 306 of the control circuitry structure 216 substantially equals a quantity of the word line exit regions 206 (FIG. 2B) of the memory array structure 102 (FIG. 2B). As shown in FIG. 3A, the second peripheral regions 306 may respectively horizontally extend in the X-direction. An individual control circuitry region 302 of the control circuitry structure 216 may be horizontally interposed between horizontally neighboring second peripheral regions 306 of the control circuitry structure 216 in the Y-direction.

Still referring to FIG. 3A, the control circuitry region 302 of the control circuitry structure 216 may respectively have the first width W₁ in the Y-direction and the first length L₁ in the X-direction orthogonal to the Y-direction. Furthermore, the first peripheral regions 304 of the control circuitry structure 216 may respectively have the first width W₁ in the Y-direction and the second length L₂ in the X-direction; and the second peripheral regions 306 of the control circuitry structure 216 may respectively have the second width W₂ in the Y-direction and the first length L₁ in the X-direction. Accordingly, a horizontal area of an individual control circuitry region 302 may be substantially the same as a horizontal area of an individual array region 202 (FIG. 2B) of the memory array structure 102 (FIG. 2B). A horizontal area of an individual first peripheral region 304 may be substantially the same as a horizontal area of an individual digit line exit regions 204 (FIG. 2B) of the memory array structure 102 (FIG. 2B), and a horizontal area of an individual second peripheral region 306 may be substantially the same as a horizontal area of an individual word line exit region 206 (FIG. 2B) of the memory array structure 102 (FIG. 2B).

As noted above, FIG. 3B includes a diagram showing different vertical cross-sectional views of the control circuitry structure 216 shown in FIG. 3A, taken about lines A″-A″ and B″-B″ of FIG. 3A. The control circuitry structure 216 may be formed to include a third base structure 308 including a semiconductor material 310 and isolation structures 312 (e.g., shallow trench isolation (STI) structures) vertically extending at least partially through the semiconductor material 310 of the second base structure 152.

The third base structure 308 may include a base material or construction upon which additional features (e.g., materials, structures, devices) of the control circuitry structure 216 may be formed. The third base structure 308 may include a semiconductor structure (e.g., a semiconductor wafer), or a base semiconductor material on a supporting structure. For example, the third base structure 308 may include a conventional silicon substrate (e.g., a conventional silicon wafer), or another bulk substrate including a semiconductor material. In some embodiments, the third base structure 308 includes a silicon wafer. The third base structure 308 may include one or more other layers, structures, and/or regions formed therein and/or thereon. The semiconductor material 310 may include any of the semiconductor materials described herein.

The isolation structures 312 may include trenches (e.g., openings, vias, apertures) within at least the semiconductor material 310 of the third base structure 308 filled with insulative material, such as one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, and TiOₓ), at least one dielectric nitride material (e.g., SiN_{y}), at least one dielectric oxynitride material (e.g., SiOₓN_{y}), at least one dielectric carboxynitride material (e.g., SiOₓC_{z}N_{y}), and amorphous carbon. In some embodiments, the further isolation structures 460 are respectively formed of and include SiOₓ (e.g., SiO₂).

As noted briefly above, the isolation structures 312 may, for example, be employed as STI structures within the third base structure 308. The isolation structures 312 may be formed to vertically extend partially (e.g., less than completely) through the third base structure 308. In some embodiments, a vertical depth (e.g., vertical height) of the isolation structures 312 is within a range of from about 200 nanometers (nm) to about 2000 nm. Each of the isolation structures 312 may be formed to exhibit substantially the same dimensions and shape as each other of the isolation structures 312, or at least one of the isolation structures 312 may be formed to exhibit one or more of different dimensions and a different shape than at least one other of the isolation structures 312. As a non-limiting example, each of the isolation structures 312 may be formed to exhibit substantially the same vertical dimension(s) and substantially the same vertical cross-sectional shape(s) as each other of the isolation structures 312; or at least one of the isolation structures 312 may be formed to exhibit one or more of different vertical dimension(s) and different vertical cross-sectional shape(s) than at least one other of the isolation structures 312. In some embodiments, the isolation structures 312 are all formed to vertically extend to and terminate at substantially the same depth within the third base structure 308 (e.g., at an interface of the semiconductor material 310 and the second insulative bonding material 314). In additional embodiments, at least one of the isolation structures 312 is formed to vertically extend to and terminate at a relatively deeper depth within the third base structure 308 (e.g., within or through the second insulative bonding material 314 of the third base structure 308) than at least one other of the isolation structures 312. As another non-limiting example, each of the isolation structures 312 may be formed to exhibit substantially the same horizontal dimension(s) and substantially the same horizontal cross-sectional shape(s) as each other of the isolation structures 312; or at least one of the isolation structures 312 may be formed to exhibit one or more of different horizontal dimension(s) (e.g., relatively larger horizontal dimension(s), relatively smaller horizontal dimension(s)) and different horizontal cross-sectional shape(s) than at least one other of the isolation structures 312. In some embodiments, at least one of the isolation structures 312 is formed to have one or more different horizontal dimensions (e.g., in the X-direction and/or in the Y-direction) than at least one other of isolation structures 312.

The control circuitry structure 216 may further include transistors 316. The transistors 316 may individually include conductively doped regions 318 (e.g., source/drain regions), a channel region 320, a gate structure 322 (e.g., a gate electrode), and a gate dielectric material 324. For an individual transistor 316, the conductively doped regions 318 thereof may be formed within the semiconductor material 310 of the third base structure 308; the channel region 320 thereof may be formed within the semiconductor material 310 of the third base structure 308 and may be horizontally interposed between the conductively doped regions 318 of the individual transistor 316; the gate structure 322 may vertically overlie and horizontally overlap the channel region 320 of the individual transistor 316; and the gate dielectric material 324 (e.g., dielectric oxide material) may be vertically interposed (e.g., in the Z-direction) between the gate structure 322 and the channel region 320.

For an individual transistor 316, the conductively doped regions 318 thereof may include the semiconductor material 310 of the third base structure doped with one or more desired conductivity-enhancing dopants. In some embodiments, the conductively doped regions 318 of the transistor 316 includes the semiconductor material 310 doped with at least one N-type dopant (e.g., one or more of phosphorus, arsenic, antimony, and bismuth). In some of such embodiments, the channel region 320 of the transistor includes the semiconductor material 310 doped with at least one P-type dopant (e.g., one or more of boron, aluminum, and gallium). In some other of such embodiments, the channel region 320 of the transistor 316 includes substantially undoped semiconductor material 310. In additional embodiments, for an individual transistor 316, the conductively doped regions 318 include the semiconductor material 310 doped with at least one P-type dopant (e.g., one or more of boron, aluminum, and gallium). In some of such additional embodiments, the channel region 320 of the transistor 316 includes the semiconductor material 310 doped with at least one N-type dopant (e.g., one or more of phosphorus, arsenic, antimony, and bismuth). In some other of such additional embodiments, the channel region 320 of the transistor 316 includes substantially undoped semiconductor material 310.

The gate structures 322 (e.g., gate electrodes, gates) may individually horizontally extend between and be employed by multiple transistors 316. The gate structures 322 may be formed of and include conductive material. The gate structures 322 may individually be substantially homogeneous, or the gate structures 322 may individually be heterogeneous. In some embodiments, the gate structures 322 are each substantially homogeneous. In additional embodiments, the gate structures 322 are each heterogeneous. Individual gate structures 322 may, for example, be formed of and include a stack of at least two different conductive materials.

The control circuitry structure 216 may further include a dielectric capping structures 326 form on upper surfaces of the gate structures 322, and dielectric spacer structures 328 on side surfaces of (e.g., horizontally bookending) the gate structures 468, the gate dielectric material 324, and the dielectric capping structures 326. In addition, the control circuitry structure 448 further includes second contact structures 330 vertically overlying and in contact (e.g., physical contact, electrical contact) with the conductively doped regions 318 of the transistors 316. In some embodiments, the second contact structures 330 vertically overlie, horizontally overlap, and physically contact the conductively doped regions 318 of the transistors 316. The second contact structures 330 may individually be formed of and include conductive material. In some embodiments, the second contact structures 330 are individually formed of and include one or more of W, Ru, Mo, and TiN_{y}.

The control circuitry structure 216 further includes second routing structures 332 vertically overlying the transistors 316. As shown in FIG. 3B, some of the second routing structures 332 may be coupled to the second contact structures 330 (and, hence, the transistors 316). The second routing structures 332 may respectively be formed of and include conductive material. In some embodiments, the second routing structures 332 are individually formed of and include one or more of W, Ru, Mo, and TiN_{y}.

The transistors 316, the second contact structures 330, and at least some of the second routing structures 332 may form control logic circuitry of various control logic devices 334 configured to control various operations of various features (e.g., the memory cells 144 (FIG. 1L)), of a microelectronic device (e.g., a memory device, such as a DRAM device) to be formed through the methods of disclosure. In some embodiments, the control logic devices 334 include complementary metal-oxide-semiconductor (CMOS) circuitry. As a non-limiting example, the control logic devices 334 may include one or more (e.g., each) of charge pumps (e.g., V_{CCP} charge pumps, V_{NEGWL} charge pumps, DVC2 charge pumps), delay-locked loop (DLL) circuitry (e.g., ring oscillators), V_{dd} regulators, drivers (e.g., main word line drivers, sub word line drivers (SWD)), page buffers, decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, array multiplexers (MUX), error checking and correction (ECC) devices, self-refresh/wear leveling devices, and other chip/deck control circuitry. Different regions of the control circuitry structure 216 may have different control logic devices 334 formed within horizontal areas thereof.

A seventh insulative material 336 may be formed on or over portions of at least the third base structure 308, the transistors 316, the second contact structures 330, the second routing structures 332, and the control logic devices 334. In some embodiments, the seventh insulative material 336 is formed of and includes a dielectric oxide material, such as SiOₓ (e.g., SiO₂). The seventh insulative material 336 may be substantially homogeneous, or the seventh insulative material 336 may be heterogeneous. An upper surface of the seventh insulative material 336 may be formed to be substantially planar. In some embodiments, the upper surface of the seventh insulative material 336 is formed vertically overlie the upper surfaces of the uppermost ones of the second routing structures 332. In additional embodiments, the upper surface of the seventh insulative material 336 is formed to be substantially coplanar with upper surfaces of uppermost ones of the second routing structures 332.

Referring next to FIG. 3C, illustrated is a diagram showing the different simplified, vertical cross-sectional views previously described with reference to FIG. 3B, at a processing stage of the method of forming the microelectronic device following the processing stage previously described with reference to FIG. 3A and FIG. 3B. As shown in FIG. 3C, a second carrier structure 338 may be attached to the control circuitry structure to form a third assembly 340. The second carrier structure 338 may include an other base structure 398 and an eighth insulative material 342 on the other base structure 398.

The other base structure 398 may include a base material or construction upon which additional features (e.g., materials, structures, devices) of the formed. In some embodiments, the other base structure 398 includes a wafer. The other base structure 398 may be formed of and include one or more of semiconductor material (e.g., one or more of a silicon material, such monocrystalline silicon or polycrystalline silicon (also referred to herein as “polysilicon”); silicon-germanium; germanium; gallium arsenide; a gallium nitride; gallium phosphide; indium phosphide; indium gallium nitride; and aluminum gallium nitride), a base semiconductor material on a supporting structure, glass material (e.g., one or more of BSP, PSG, FSG, BPSG, aluminosilicate glass, an alkaline earth boro-aluminosilicate glass, quartz, titania silicate glass, and soda-lime glass), and ceramic material (e.g., one or more of p-AlN, SOPAN, AlN, aluminum oxide (e.g., sapphire; α-Al₂O₃), and silicon carbide). By way of non-limiting example, the other base structure 398 may include a semiconductor wafer (e.g., a silicon wafer), a glass wafer, or a ceramic wafer. The other base structure 398 may include one or more layers, structures, and/or regions formed therein and/or thereon.

The eighth insulative material 342 may cover one or more surfaces of the other base structure 486. In some embodiments, the eighth insulative material 342 is formed of and includes a dielectric oxide material, such as SiOₓ (e.g., SiO₂). The third insulative material 488 may be substantially homogeneous, or the eighth insulative material 342 may be heterogeneous.

To attach the second carrier structure 338 to the control circuitry structure 216 to form the second assembly 142, the eighth insulative material 342 of the first carrier structure 150 may be provided in physical contact with at least the seventh insulative material 336 of the control circuitry structure 216, and the eighth insulative material 342 and the seventh insulative material 336 may be exposed to annealing conditions to form bonds (e.g., oxide-to-oxide bonds) between the eighth insulative material 342 and the seventh insulative material 336. By way of non-limiting example, the eighth insulative material 342 and the seventh insulative material 336 may be exposed to a temperature greater than or equal to about 400° C. (e.g., within a range of from about 400° C. to about 800° C., greater than about 800° C.) to form oxide-to-oxide bonds between the eighth insulative material 342 and the seventh insulative material 336. In some embodiments, the eighth insulative material 342 and the seventh insulative material 336 are exposed to at least one temperature greater than about 800° C. to form oxide-to-oxide bonds between the eighth insulative material 342 and the seventh insulative material 336.

Referring next to FIG. 3D, illustrated is a diagram showing the different simplified, vertical cross-sectional views previously described with reference to FIG. 3B, at a processing stage of the method of forming the microelectronic device following the processing stage previously described with reference to FIG. 3C. As shown in FIG. 3D, the third assembly 340 may be vertically inverted, and then at least one thinning process (e.g., a CMP process; an etching process, such as a conventional dry etching process or a wet etching process) may be performed on the third base structure 308 to remove upper portions (following vertical inversion) of at least the semiconductor material 310 (and, optionally, the isolation structures 312) to expose the isolation structures 312. The remaining portions of the semiconductor material 310 and the isolation structures 312 may be formed to exhibit a desired vertical height (e.g., in the Z-direction) through the material removal process, such as a vertical height less than or equal to about 1500 nm, such as within a range of from about 200 nm to about 1500 nm, from about 200 nm to about 1000 nm, from about 200 nm to about 500 nm, or about 200 nm.

Still referring to FIG. 3D, after the thinning process, a ninth insulative material 344 may be formed one or over upper surfaces of the remaining portions of the semiconductor material 310 and the isolation structures 312. In some embodiments, the ninth insulative material 344 is formed of and includes a dielectric oxide material, such as SiOₓ (e.g., SiO₂). The ninth insulative material 344 may be substantially homogeneous, or the ninth insulative material 344 may be heterogeneous. An upper surface of the ninth insulative material 344 may be formed to be substantially planar. As is described in greater detail below, the ninth insulative material 344 may be utilized to bond the third assembly 340 and the control circuitry structure 216 to the memory array structure 102 through an oxide-to-oxide bond.

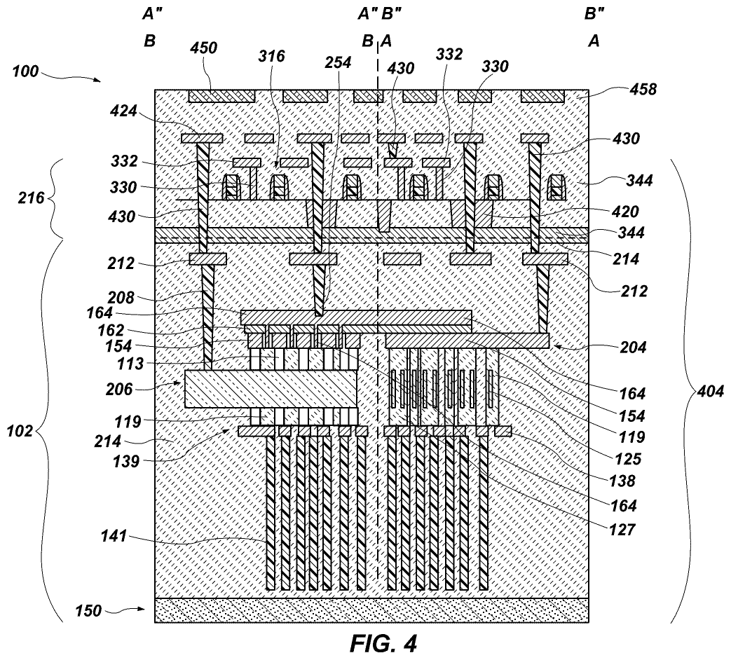

FIG. 4 is a diagram showing different vertical cross-sectional views of a fourth assembly 404, which includes the control circuitry structure 216 bonded to the memory array structure 102. For clarity and ease of depiction, not every element of the fourth assembly 404 is depicted within FIG. 4; however, the fourth assembly 404 may include any of the materials, structures, and elements (e.g., dielectric materials, dielectric liner materials, structures) of the memory array structure 102 and the control circuitry structure 216 described above in regard to FIG. 1A through FIG. 3D.

To form the fourth assembly 404, the ninth insulative material 344 of the control circuitry structure 216 may be put in physical contact with the sixth insulative material 214 of the memory array structure 102, and then the ninth insulative material 344 and the sixth insulative material 214 may be exposed to annealing conditions to form bonds (e.g., dielectric-to-dielectric bonds, such as oxide-to-oxide bonds) between the ninth insulative material 344 and the sixth insulative material 214. By way of non-limiting example, the ninth insulative material 344 and the sixth insulative material 214 may be exposed to a temperature greater than or equal to about 400° C. (e.g., within a range of from about 400° C. to about 800° C., greater than about 800° C.) to form bonds between the ninth insulative material 344 and the sixth insulative material 214. While FIG. 4 includes a dashed line representing an initial interface location between the memory array structure 102 and the control circuitry structure 216 before the bonding process, the ninth insulative material 344 and the sixth insulative material 214 may be integral and continuous with one another following the bonding process. The control circuitry structure 216 may be attached to the memory array structure 102 without a bond line. Following the attachment of the control circuitry structure 216 to the memory array structure 102, the second carrier structure 338 (FIG. 3D) may be removed.

For the formation of the fourth assembly 404, a front side of the control circuitry structure 216 of the control circuitry structure 216 may be considered to be a side (e.g., end surface) most proximate to the control logic devices 334 (e.g., most proximate to the second routing structures 332), and a back side of the control circuitry structure 216 may be considered to be an additional side (e.g., additional end surface) relatively more distal from the control logic devices 334 (e.g., most proximate to the ninth insulative material 344) than the front side. In addition, a front side of the memory array structure 102 may be considered to be a side (e.g., end surface) most proximate to the first carrier structure 150, and a back side of the memory array structure 102 may be considered to be an additional side (e.g., additional end surface) most proximate to the first routing structures 212. Accordingly, in the configuration shown in FIG. 4, the fourth assembly 404 may be formed to have a so-called “back-to-back” (B2B) arrangement of the control circuitry structure 216 relative to the memory array structure 102.

In view of the foregoing, the control circuitry structure 216 may be attached to a side of the memory array structure 102 vertically closer to the access devices 134 of the memory cells 144 than the storage node devices 141 of the memory cells 144. Put another way, the control circuitry structure 216 may be attached to a side of the memory array structure 102 opposite the multi-storage node structure 140. Furthermore, the shield structure 164 and digit line structures 154 may be vertically interposed between the control circuitry structure 216 and the memory cells 144, the access devices 134 may be vertically interposed between the multi-storage node structure 140 and the control circuitry structure 216, and the access devices 134 may be vertically interposed between the multi-storage node structure 140 and the shield structure 164 and digit line structures 154.

Still referring to FIG. 4, following the formation of the fourth assembly 404, at least some of the isolation structures 312 of the second microelectronic device structure may vertically overlie and horizontally overlap (e.g., in the X-direction and the Y-direction shown in FIG. 3A) at least some of the first routing structures 212 of the memory array structure 102. The horizontal positions of the isolation structures 312 may facilitate the formation of additional conductive contact structures vertically extending through the at least some of the isolation structures 312 and to at least some of the first routing structures 212.

In particular, following the formation of the fourth assembly 404, third routing structures 424 may be formed vertically over the control logic devices 334. In addition, third contact structures 430 may be formed to couple at least some of the third routing structures 424 to at least some of the control logic devices 334, and third contact structures 430 may be formed to couple at least some of the third routing structures 424 to at least some of the first routing structures 212. Furthermore, as described in further detail below, back-end-of-line (BEOL) structures may be formed vertically over the third routing structure 424.

The third routing structures 424 may be formed to horizontally extend in desirable paths over the control logic devices 334. In some embodiments, some of the third routing structures 424 may be coupled to some of the second routing structures 332 (and, hence, at least some of the control logic devices 334) by way of the third contact structures 430. For example, the third contact structures 430 may vertically extend from the some of the third routing structures 424 to the some of the second routing structures 332.

As mentioned briefly above, some of the third contact structures 430 may be formed to vertically extend from some of the third routing structures 424 vertically overlying the control logic devices 334 to some of the first routing structures 212 vertically underlying the control logic devices 334. One or more (e.g., each) of the third contact structures 430 may be formed to horizontally overlap and vertically extend through one or more of the isolation structures 312 (e.g., STI structures) of the control circuitry structure 216. Optionally, one or more other of the third contact structures 430 may be formed to horizontally overlap and vertically extend through the semiconductor material 310 of the control circuitry structure 216. The third contact structures 430 may facilitate (in combination with at least the second contact structures 330, the second routing structures 332, the interconnect structures 208, the RDM structures 138, the digit line structures 154, and the word line structures 125) operable communication between the control logic devices 334 and each of the memory cells 144 vertically thereunder. The third routing structures 424 and the third contact structures 430 may respectively be formed of and include conductive material. In some embodiments, the third routing structures 424 and the third contact structures 430 are individually formed of and include one or more of W, Ru, Mo, and TiN_{y}.

As noted above in regard to FIG. 1GA, merged word line structures 125 within the thin x-axis trenches 122 may form a shield gate 172 or back gate that shields word line structures 125 from cross-interference between word line structures 125 within the wide x-axis trenches 121. For example, the shield gates 172 may control electrical field interference between the access devices 134. In some embodiments, the shield gates 172 are formed from tungsten or another conductive material. In one or more embodiments, the shield gates 172 are formed from a semiconductor material (e.g., polysilicon). Furthermore, the shield gates 172 may be operably connected to a respective voltage supply at an edge of the array. The shield gates 172 may improve ION boost, IOFF control, and/or leakage management of the access devices 134.

As previously mentioned, BEOL structures may be formed vertically over the third routing structures 424. For example, at least one additional routing tier (e.g., at least two additional routing tiers) including additional routing structures may be formed over the third routing structure 424; and pad structures 450 may be formed over the additional routing structures. In addition, additional contact structures may be formed to couple different additional routing structures with one another, different third routing structures 424, and/or different pad structures 450, as desired. Some of the additional routing structures may be coupled to some of the third routing structures 424 by way of some of the additional contact structures. Some of the additional routing structures may be coupled to some other of the additional routing structures by way of some other of the additional contact structures, and some of the additional routing structures may be coupled to some of the pad structures 450 by way of yet still other of the additional contact structures. The additional routing structures, the pad structures 450, and the additional contact structures may respectively be formed of and include conductive material. In some embodiments, the additional routing structures, the pad structures 450, and the additional contact structures are individually formed of and include one or more of W, Cu, Al, Ru, Mo, and TiN_{y}.

A tenth insulative material 458 may be formed on or over portions of at least the seventh insulative material 336 (FIG. 3D), the third routing structures 424, the third contact structures 430, the third contact structures 653, the additional routing structures, the additional contact structures, and the pad structures 450. In some embodiments, the tenth insulative material 458 may is formed of and includes a dielectric oxide material, such as SiOₓ (e.g., SiO₂). The tenth insulative material 458 may be substantially homogeneous, or the tenth insulative material 458 may be heterogeneous. In some embodiments, an upper surface of the tenth insulative material 458 is formed to be substantially coplanar with upper surfaces of the pad structures 450. In additional embodiments, the upper surface of the tenth insulative material 458 is formed to vertically overlie the upper surfaces of the pad structures 450. In such embodiments, openings may be formed within the tenth insulative material 458 to at least partially expose (and, hence, facilitate access to) the upper surfaces of the pad structures 450.

As shown in FIG. 4, the method described above with reference to FIG. 1A through FIG. 4 may effectuate the formation of a microelectronic device 100 (e.g., a memory device, such as a DRAM device) including the features (e.g., regions, structures, materials, devices) previously described herein. Furthermore, at least some of the pad structures 450, at least some of the additional routing structures, at least some of the third routing structures 424, and at least some of the additional contact structures may be employed as global routing and interconnect structures for the microelectronic device 100 to, for example, receive global signals from an external bus, and to relay the global signals to other components (e.g., structures, devices) of the microelectronic device 100.

The configuration of the microelectronic device 100 may facilitate enhanced device performance (e.g., speed, data transfer rates, power consumption) relative to conventional microelectronic device configurations. For example, the configurations and positions of the memory array structure 102 relative to the control logic devices 334 may facilitate enhanced array efficiency for the memory array structure 102, and may also control stresses while attaching (e.g., bonding) the control circuitry structure 216 (including the control circuitry structure 216 thereof) to the memory array structure 102 as well as during material thinning processes performed on the control circuitry structure 216 (e.g., facilitating relatively reduced vertical dimensions of the semiconductor material 310 of the control circuitry structure 216). Furthermore, the B2B attachment of the control circuitry structure 216 to the memory array structure 102 may provide enhanced alignment margin when compared to conventional methods. Moreover, the method described above with reference to FIG. 1A through FIG. 4 may resolve limitations on array (e.g., memory cell array) configurations, control logic device configurations, and associated device performance that may otherwise result from thermal budget constraints imposed by the formation and/or processing of arrays (e.g., memory cell arrays) of a microelectronic device.

Furthermore, the configuration and position of the memory array structure 102 (e.g., the proximity of the digit line structures 154 and word line structures 125) relative to the control logic devices 334 may reduce a distance between the digit line structures 154 and a sense amplifier (e.g., a complementary metal-oxide-semiconductor (CMOS) latch). Additionally, the configuration and position of the memory array structure 102 (e.g., the proximity of the digit line structures 154 and word line structures 125) relative to the control logic devices 334 of the present disclosure removes congestion between the digit line structures 154 and a sense amplifier typically caused by a multi-storage node structure. As a result, a number of interconnects and contacts needed to create connections between elements of the microelectronic device 100 are reduced. Because interconnects and contacts and the processes (e.g., cycle time) needed to form the interconnects and contacts are reduced, the methods and processes described above with reference to FIG. 1A through FIG. 4 reduce a cost of fabricating microelectronic devices in comparison to conventional methods.

Moreover, because a distance between digit line structures 154 and a sense amplifier is reduced by the structures and methods described herein, the structures and methods described herein may improve array efficiency and result in smaller sockets and contacts. Additionally, because a distance between digit line structures 154 and a sense amplifier is reduced in comparison to conventional microelectronic devices, contact structures (e.g., interconnect structures) may be smaller and shorter, which results in reduced interference (e.g., parasitic interference) between contact structures. Moreover, the shorter distance between digit line structures 154 and a sense amplifier improves sense amplified signal margin (i.e., signal to noise margin). Additionally, the word line structures 125 are closer to the sub word line drivers (SWD) than conventional devices, which improves the associate data path and refresh-RC delay.

Thus, in accordance with some embodiments of the disclosure, a microelectronic device includes a memory array structure including an array region having memory cells within a horizontal area of the array region. Each of the memory cells may include an access device and a storage node device vertically underlying and coupled to the access device. The microelectronic device further includes a control circuitry structure vertically overlying and attached to the memory array structure at a side of the memory array structure vertically closer to the access devices of the memory cells than the storage node devices of the memory cells.

Furthermore, in accordance with some embodiments of the disclosure, a method of forming a microelectronic device includes forming a memory array structure including an array region having memory cells within a horizontal area of the array region, each of the memory cells including an access device and a storage node device vertically underlying and coupled to the access device, forming a control circuitry structure including control logic devices, and attaching the control circuitry structure to a side of the memory array structure vertically closer to the access devices of the memory cells than the storage node devices of the memory cells.

Moreover, in accordance with embodiments of the disclosure, a memory device includes a memory array structure and a control circuitry structure. The memory array structure may include an array region having dynamic random-access memory (DRAM) cells therein, each of the DRAM cells comprising an access device and a storage node device vertically underlying and coupled to the access device. The control circuitry structure may vertically overlie and be attached to the memory array structure at a side of the memory array structure vertically closer to the access devices of the DRAM cells than the storage node devices of the DRAM cells.

One or more embodiments of the disclosure includes a method of forming a microelectronic device. The method may include forming a memory array structure including forming an array region having dynamic random-access memory (DRAM) cells within a horizontal area of the array region, each of the DRAM cells comprising an access device and a storage node device vertically underlying and coupled to the access device, forming digit line structures overlying the access devices of the DRAM cells and coupling the digit line structures to the access devices of the DRAM cells, and forming a shield structure overlying digit line structures. The method may further include forming a control circuitry structure comprising control logic devices and attaching the control circuitry structure to the memory array structure on a side of the shield structure opposite the access devices of the DRAM cells.

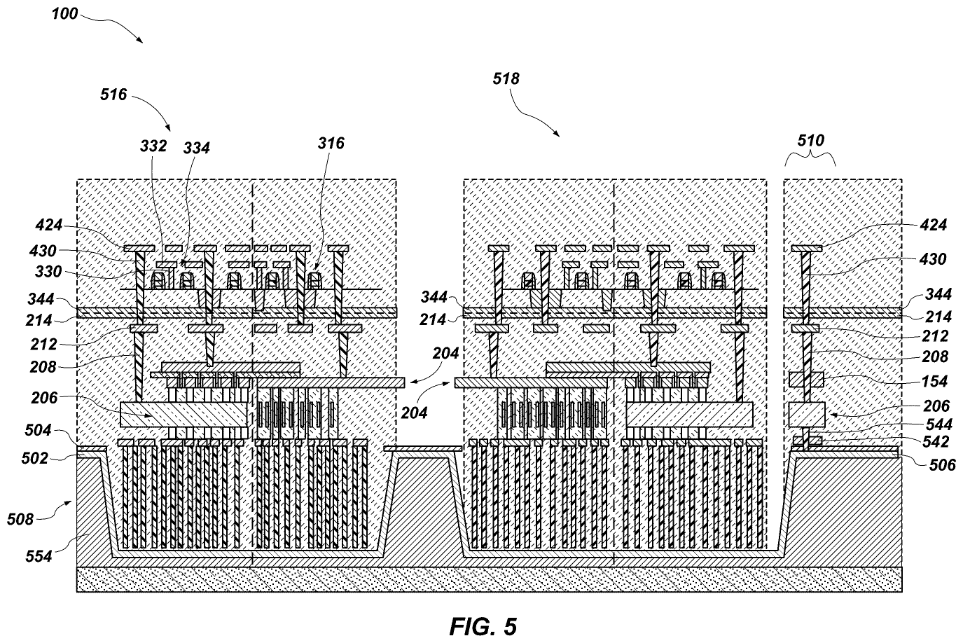

FIG. 5 is a simplified, schematic cross-sectional view of neighboring fourth assemblies (e.g., tiles, patches, subarrays), such as the fourth assemblies 404 described above in regard to FIG. 4, within horizontal area of a patch region of a bank region of the microelectronic device 100. For instance, the microelectronic device 100 may include a first fourth assembly 516 and a second fourth assembly 518 oriented on and overlying portions of a shared carrier 508. While not every element of the first fourth assembly 516 and the second fourth assembly 518 is depicted within FIG. 5 for clarity and ease of depiction, the first fourth assembly 516 and the second fourth assembly 518 may include any of the materials, structures, and elements (e.g., dielectric materials, dielectric liner materials, structures, etc.) of the fourth assemblies 404 (FIG. 4) described above in regard to FIG. 1A through FIG. 4. As will be recognized by one of ordinary skill in the art, while only two fourth assemblies are depicted in FIG. 5, the disclosure is not so limited, and the microelectronic device 100 and patch regions of the microelectronic device 100 may include additional fourth assemblies.

As depicted in FIG. 5, within a patch region of a bank region of the microelectronic device 100, the first fourth assembly 516 and the second fourth assembly 518 may be overlying the shared carrier 508. In some embodiments, the shared carrier 508 may include a semiconductor material 504 (e.g., one or more of a silicon material, such monocrystalline silicon or polycrystalline silicon (also referred to herein as “polysilicon”); silicon-germanium; germanium; gallium arsenide; a gallium nitride; gallium phosphide; indium phosphide; indium gallium nitride; and aluminum gallium nitride) overlying a cell plate 502. The cell plate 502 may include a conductive material 506 (e.g., tungsten). Additionally, in some embodiments, the cell plate 502 of the shared carrier 508 may form an electrode of a common cell multi-capacitor structure (e.g., common structure of metal-insulator-metal (MIM) capacitors, common structure of metal-insulator-semiconductor (MIS) capacitors). In some embodiments, the cell plate 502 is the same structure as the cell plate 149 described above in regard to FIG. 1L, and the semiconductor material 504 is the same structure as the conductive material 148 described above in regard to FIG. 1L. The cell plate 502 may overlie a dielectric structure 554. The dielectric structure 554 may include any of the dielectric and/or insulative materials described herein. In some embodiments, the dielectric structure 554 is the same structure as the fourth insulative material 153 (FIG. 1N).

In one or more embodiments, the cell plate 502 and the associated cell capacitor structure is utilized to regulate voltages supplied to one or more of charge pumps (e.g., V_{CCP} charge pumps, V_{NEGWL} charge pumps, DVC2 charge pumps), delay-locked loop (DLL) circuitry (e.g., ring oscillators), V_{dd} regulators, drivers (e.g., main word line drivers, sub word line drivers (SWD)), page buffers, decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, array multiplexers (MUX), error checking and correction (ECC) devices, self-refresh/wear leveling devices, and other chip/deck control circuitry. For instance, the cell plate 502 may support and/or form a portion of so called “decoupling capacitors” and/or “pump capacitors.”

Referring still to FIG. 5, in some embodiments, the cell plate 502 may be continuous between the first fourth assembly 516 and the second fourth assembly 518 (e.g., tiles, patches, subarrays).

Furthermore, the microelectronic device 100 may include contact assemblies 510 operably coupled to the cell plate 502. The contact assemblies 510 may be formed at or proximate horizontal edges of a group (e.g., array) of fourth assemblies 404 (e.g., at an edge of array (EOA)). In other words, the contact assemblies 510 coupled to the cell plate 502 may be formed proximate horizontal perimeters of the patch regions or bank regions of the microelectronic device 100.

In some embodiments, the contact assemblies 510 of the cell plate 502 include one or more existing structures. For instance, the contact assemblies 510 may include one or more of RDM structures 138 of the RDL tier 139, interconnect structures 208, first routing structures 212, third contact structures 430, or third routing structures 424. Additionally, each contact assembly 510 may include a cell plate contact 544 and a fourth routing structure 542. In some embodiments, the cell plate contact 544 may be in contact (e.g., physical and electrical contact) with the cell plate 502 and may extend from the cell plate 502 to the fourth routing structure 542. In one or more embodiments, the fourth routing structure 542 may include an RDM structure 138, and the fourth routing structure 542 may be operably coupled to one or more of interconnect structures 208, first routing structures 212, third contact structures 430, or third routing structures 424.

Additionally, the cell plate contact 544 may not be directly vertically aligned (i.e., aligned in a vertical direction) with the digit line structures 154 or the word line structures 125, and therefore, does not interfere with the digit line structures 154 or the word line structures 125. Furthermore, the contact assembly 510 (i.e., the cell plate contact 544) may contact the cell plate 502 through the semiconductor material 504. In other words, the contact assembly 510 (i.e., the cell plate contact 544) may contact the cell plate 502 from a polysilicon or SiGe side of the shared carrier 508.

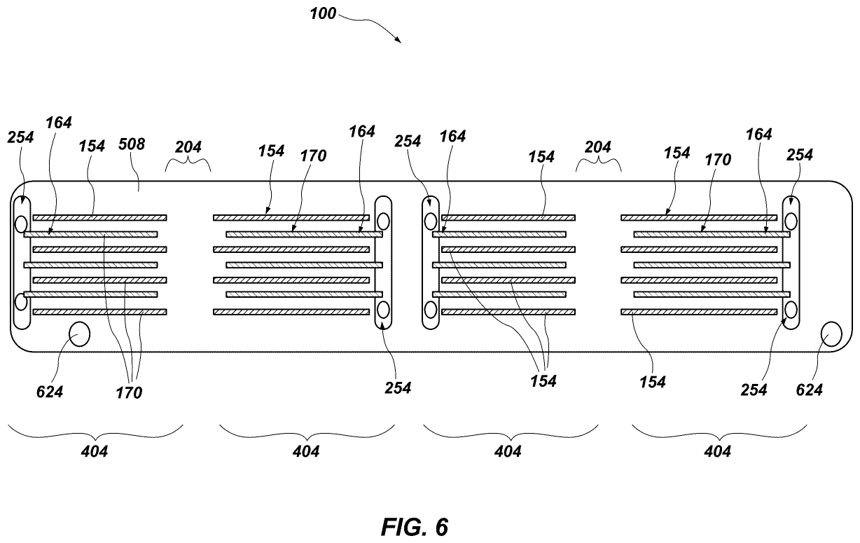

FIG. 6 is a simplified, schematic, top cross-sectional view of a microelectronic device 100 including multiple fourth assemblies 404 oriented over a shared carrier 508 (e.g., a semiconductor material 504 (FIG. 5) and cell plate 502 (FIG. 5)) and back-to-back. Not every element of the fourth assemblies 404 is depicted within FIG. 6 for clarity and ease of depiction, and the fourth assemblies 404 may include any of the materials, structures, and elements (e.g., dielectric materials, dielectric liner materials, structures, etc.) of the fourth assemblies 404 described above in regard to FIG. 1A through FIG. 5.

As is shown in FIG. 6, and as noted above, the contact assemblies 510 (FIG. 5) and the associated cell plate contacts 544 may be located at or proximate horizontal edges of patch region of the microelectronic device 100 (e.g., edge of array (EOA)). For instance, at least one first contact assembly 510 may be operably coupled to the cell plate 502 of the shared carrier 508 by way of a cell plate contact 544 proximate a horizontal boundary of a patch region at a longitudinal end of the patch region of the microelectronic device 100, and at least one second contact assembly may be operably coupled to the cell plate 502 of the shared carrier 508 by way of a cell plate contact 544 proximate a horizontal boundary of the patch region at a lateral end of the patch region of the microelectronic device 100. Additionally, in view of the foregoing, the X and Y coordinates of the cell plate contacts 544 are flexible because the contact assemblies 510 do not interfere with the digit line structures 154 or the word line structures 125 and are located proximate the horizontal boundary of the patch region.

Additionally, the shield contacts 254 of the shield structures 164 of the fourth assemblies 404 may be formed and located at or proximate horizontal edges of the fourth assemblies 404. In other words, the shield contacts 254 of the shield structures 164 may be formed proximate horizontal perimeters of the fourth assemblies 404. As noted above, the shield contacts 254 may be utilized to bias the shield structures 164 with a voltage to control or enhance protection provided by the shield structure 164 from undesirable electrical interference (e.g., electromagnetic interference (EMI)). In some embodiments, the shield contacts 254 of the fourth assemblies 404 may be formed proximate or at horizontal boundaries of the fourth assemblies 404 opposite digit line exit regions 204 of the fourth assemblies 404. As a result, within a group of the fourth assemblies 404 oriented within a patch region of the microelectronic device 100, portions of the fourth assemblies 404 including the shield contacts 254 may face each other.

As is shown in FIG. 6, the projections 170 of the shield structures 164 may be horizontally interposed between neighboring digit line structures 154.

The configuration of the microelectronic device 100 may facilitate enhanced device performance (e.g., speed, data transfer rates, power consumption) relative to conventional microelectronic device configurations. For example, the continuous shared carrier 508 between fourth assemblies 404 and the locations of the cell plate contacts 544 and the shield contacts 254 may facilitate enhanced array efficiency for the memory array structure 102.

Thus, in accordance with some embodiments of the disclosure, a microelectronic device includes a first memory array structure including a first array region including first memory cells within a horizontal area of the first array region, each of the first memory cells including a first access device and a first storage node device vertically underlying and coupled to the first access device, a first control circuitry structure vertically overlying and attached to the first memory array structure at a boundary of the first memory array structure vertically closer to the first access devices of the first memory cells than the first storage node devices of the first memory cells, and a first shield structure vertically interposed between the first memory cells of the first memory array structure and the first control circuitry structure.

Thus, in accordance with embodiments of the disclosure, a method of forming a microelectronic device includes forming a memory array structure including an array region having volatile memory cells within a horizontal area of the array region, the volatile memory cells respectively including a vertical channel access device and a storage node device vertically underlying and coupled to the vertical channel access device, forming a control circuitry structure comprising control logic devices, and bonding the control circuitry structure to a surface of the memory array structure vertically closer to the vertical channel access devices of the volatile memory cells than the storage node devices of the volatile memory cells.

Moreover, in accordance with some embodiments of the disclosure, method of forming a microelectronic device includes forming a memory array structure, forming, separate from the memory array structure, a control circuitry structure including control logic circuitry; and bonding the control circuitry structure to the memory array structure. Forming the memory array structure may include forming an array region having dynamic random-access memory (DRAM) cells within a horizontal area thereof, the DRAM cells including vertical channel transistors and capacitors vertically underlying and coupled to the vertical channel transistors, forming digit line structures vertically above and coupled to the vertical channel transistors the DRAM cells, and forming at least one shield structure at least partially vertically above and horizontally overlapping at least some of the digit line structures. The control circuitry structure may be bonded to the memory array structure such that: transistors of the control logic circuitry are vertically positioned relatively closer to the shield structure of the memory array structure than are routing structures of the control logic circuitry; and the vertical channel transistors of the DRAM cells are vertically positioned relatively closer to the control logic circuitry of the control circuitry structure than are the capacitors of the DRAM cells.

Additionally, in accordance with some embodiments of the disclosure, method of forming a microelectronic device includes forming a first assembly including forming a first memory array structure comprising a first array region comprising first memory cells within a horizontal area of the first array region, each of the first memory cells comprising a first access device and a first storage node device vertically underlying and coupled to the first access device, forming a first shield structure overlying first digit line structures of the first memory array structure, forming a first control circuitry structure comprising first control logic devices; and attaching the first control circuitry structure to a side of the first memory array structure vertically closer to the first access devices of the first memory cells than the first storage node devices of the first memory cells such that the first shield structure is vertically interposed between the first memory cells of the first memory array structure and the first control circuitry structure.

Forming the first shield structure may include forming the first shield structure to include first projections that extend vertically between horizontally neighboring first digit line structures of the first memory array structure.

The method may further include forming a first shield contact proximate a horizontal boundary of the first assembly and operably coupling the first shield structure to the first shield contact.

The method may further include forming a second assembly comprising: forming a second memory array structure comprising a second array region comprising second memory cells within a horizontal area of the second array region, each of the second memory cells comprising a second access device and a second storage node device vertically underlying and coupled to the second access device; forming a second shield structure overlying second digit line structures of the second memory array structure; forming a second control circuitry structure comprising second control logic devices; and attaching the second control circuitry structure to a side of the second memory array structure vertically closer to the second access devices of the second memory cells than the second storage node devices of the second memory cells such that the second shield structure is vertically interposed between the second memory cells of the second memory array structure and the second control circuitry structure.

The method may further forming a second shield contact proximate a horizontal boundary of the second assembly and operably coupling the second shield structure to the second shield contact.

The method may further include orienting the first assembly and the second assembly on a shared carrier such that the horizontal boundary of the first assembly most proximate the first shield contact faces the horizontal boundary of the second assembly most proximate the second shield contact.

The shared carrier may further include a semiconductor material overlying the cell plate.

The method may further include forming at least one contact assembly proximate a horizontal boundary of a patch region of the microelectronic device and operably coupling the at least one contact assembly to the cell plate of the shared carrier.

One or more embodiments of the disclosure include a microelectronic device. The microelectronic device may include a memory array structure and a control circuitry structure bonded to the memory array structure. The memory array structure may include volatile memory cells respectively including a storage node structure, a vertical access device vertically overlying the storage node structure and including: a semiconductor pillar comprising a source region, a drain region, and a channel region vertically extending from and between the source region and the drain region, and a gate electrode horizontally neighboring a sidewall of the semiconductor pillar, the gate electrode vertically overlapping the channel region of the semiconductor pillar, digit lines vertically overlying and coupled to the volatile memory cells. The control circuitry structure may include control logic devices coupled to at least some of the volatile memory cells of the memory array structure and respectively including conductive routing; and transistors vertically interposed positioned between the conductive routing and the digit lines of the memory array structure.

Some embodiments include a micro electronic device. The microelectronic device may include a first assembly oriented on and attached to a shared carrier, the first assembly comprising: a first memory array structure comprising first memory cells, each of the first memory cells comprising a first access device and a first storage node device vertically underlying and coupled to the first access device; a first control circuitry structure vertically overlying and attached to the first memory array structure at a side of the first memory array structure vertically closer to the first access devices of the first memory cells than the first storage node devices of the first memory cells; a first shield contact formed proximate a horizontal boundary of the first assembly; and a first shield structure operably coupled to the first shield contact and vertically interposed between the first memory cells of the first memory array structure and the first control circuitry structure; and a second assembly oriented on and attached to the shared carrier and horizontally neighboring the first assembly, the second assembly comprising: a second memory array structure comprising second memory cells, each of the second memory cells comprising a second access device and a second storage node device vertically underlying and coupled to the second access device; a second control circuitry structure vertically overlying and attached to the second memory array structure at a side of the second memory array structure vertically closer to the second access devices of the second memory cells than the second storage node devices of the second memory cells; a second shield contact formed proximate a horizontal boundary of the second assembly; and a second shield structure operably coupled to the second shield contact and vertically interposed between the second memory cells of the second memory array structure and the second control circuitry structure.

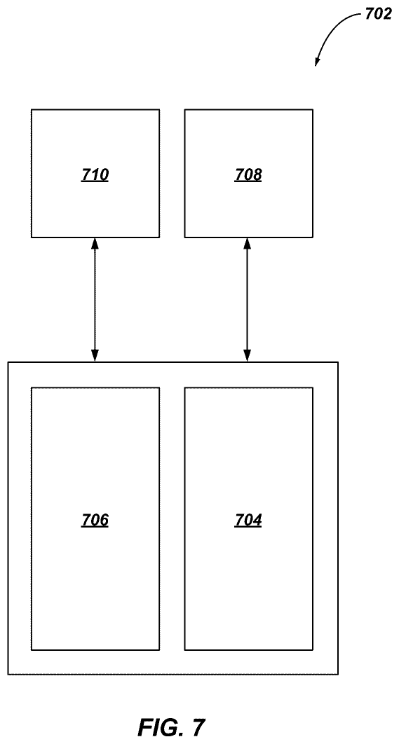

Microelectronic devices (e.g., the microelectronic device 100 (FIG. 5)) in accordance with embodiments of the disclosure may be used in embodiments of electronic systems of the disclosure. For example, FIG. 7 is a block diagram illustrating an electronic system 702 according to embodiments of disclosure. The electronic system 702 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPAD® or SURFACE® tablet, an electronic book, a navigation device, etc. The electronic system 702 includes at least one memory device 704. The memory device 704 may comprise, for example, a microelectronic device (e.g., the microelectronic device 100 (FIG. 5)) previously described herein. The electronic system 702 may further include at least one electronic signal processor device 706 (often referred to as a “microprocessor”). The electronic signal processor device 706 may, optionally, comprise a microelectronic device (e.g., the microelectronic device 100 (FIG. 5)) previously described herein. While the memory device 704 and the electronic signal processor device 706 are depicted as two (2) separate devices in FIG. 7, in additional embodiments, a single (e.g., only one) memory/processor device having the functionalities of the memory device 704 and the electronic signal processor device 706 is included in the electronic system 702. In such embodiments, the memory/processor device may include a microelectronic device (e.g., the microelectronic device 100 (FIG. 5)) previously described herein. The electronic system 702 may further include one or more input devices 708 for inputting information into the electronic system 702 by a user, such as, for example, a mouse or other pointing device, a keyboard, a touchpad, a button, or a control panel. The electronic system 702 may further include one or more output devices 710 for outputting information (e.g., visual or audio output) to a user such as, for example, a monitor, a display, a printer, an audio output jack, a speaker, etc. In some embodiments, the input device 708 and the output device 710 comprise a single touchscreen device that can be used both to input information to the electronic system 702 and to output visual information to a user. The input device 708 and the output device 710 may communicate electrically with one or more of the memory device 704 and the electronic signal processor device 706.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalent. For example, elements and features disclosed in relation to one embodiment may be combined with elements and features disclosed in relation to other embodiments of the disclosure.

All references cited herein are incorporated herein in their entireties. If there is a conflict between definitions herein and in an incorporated reference, the definition herein shall control.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternate useful combinations of the elements described, will become apparent to those skilled in the art from the description. Such modifications and embodiments also fall within the scope of the appended claims and equivalents.

What is claimed is:

1. A microelectronic device, comprising:
a first memory array structure comprising:
a first array region comprising first memory cells within a horizontal area of the first array region, each of the first memory cells comprising a first access device and a first storage node device vertically underlying and coupled to the first access device;
a first control circuitry structure vertically overlying and attached to the first memory array structure at a boundary of the first memory array structure vertically closer to the first access device of the first memory cells than the first storage node devices of the first memory cells; and
a first shield structure vertically interposed between the first memory cells of the first memory array structure and the first control circuitry structure.

2. The microelectronic device of claim 1, further comprising first digit line structures vertically overlying the first access device of the first memory cells, and wherein the first shield structure vertically overlies the first digit line structures.

3. The microelectronic device of claim 2, wherein the first shield structure comprises first projections that extend vertically between pairs of the first digit line structures horizontally neighboring one another.

4. The microelectronic device of claim 1, wherein the first shield structure is coupled to a first shield contact proximate a horizontal boundary of the first memory array structure.

5. The microelectronic device of claim 1, further comprising a shared carrier over which the first memory array structure is oriented and attached, wherein the shared carrier comprises a cell plate forming an electrode of a shared multi-capacitor structure.

6. The microelectronic device of claim 5, further comprising:
a second memory array structure comprising a second array region comprising second memory cells within a horizontal area of the second array region, each of the second memory cells comprising a second access device and a second storage node device vertically underlying and coupled to the second access device, the second memory array structure being oriented over and attached to the shared carrier and horizontally neighboring the first memory array structure and first control circuitry structure;
a second control circuitry structure vertically overlying and attached to the second memory array structure at a boundary of the second memory array structure vertically closer to the second access devices of the second memory cells than the second storage node devices of the second memory cells; and
a second shield structure vertically interposed between the second memory cells of the second memory array structure and the second control circuitry structure.

7. The microelectronic device of claim 6, wherein the second shield structure is coupled to a second shield contact proximate a horizontal boundary of the second memory array structure.

8. The microelectronic device of claim 7, wherein a horizontal boundary of the first memory array structure most proximate a first shield contact faces a horizontal boundary of the second memory array structure most proximate the second shield contact.

9. The microelectronic device of claim 5, wherein the shared carrier further comprises semiconductor material overlying the cell plate.

10. The microelectronic device of claim 5, further comprising at least one contact assembly of the shared carrier formed proximate a horizontal boundary of a patch region of the microelectronic device.

11. A microelectronic device, comprising:
a first assembly oriented on and attached to a shared carrier, the first assembly comprising:
a first memory array structure comprising first memory cells, each of the first memory cells comprising a first access device and a first storage node device vertically underlying and coupled to the first access device;
a first control circuitry structure vertically overlying and attached to the first memory array structure at a side of the first memory array structure vertically closer to the first access devices of the first memory cells than the first storage node devices of the first memory cells;
a first shield contact formed proximate a horizontal boundary of the first assembly; and
a first shield structure operably coupled to the first shield contact and vertically interposed between the first memory cells of the first memory array structure and the first control circuitry structure; and
a second assembly oriented on and attached to the shared carrier and horizontally neighboring the first assembly, the second assembly comprising:
a second memory array structure comprising second memory cells, each of the second memory cells comprising a second access device and a second storage node device vertically underlying and coupled to the second access device;
a second control circuitry structure vertically overlying and attached to the second memory array structure at a side of the second memory array structure vertically closer to the second access devices of the second memory cells than the second storage node devices of the second memory cells;
a second shield contact formed proximate a horizontal boundary of the second assembly; and
a second shield structure operably coupled to the second shield contact and vertically interposed between the second memory cells of the second memory array structure and the second control circuitry structure.

12. The microelectronic device of claim 11, wherein the horizontal boundary of the first assembly most proximate the first shield contact faces the horizontal boundary of the second assembly most proximate the second shield contact.

13. The microelectronic device of claim 11, wherein the shared carrier comprises a shared, multi-capacitor structure comprising semiconductor material overlying an electrode.

14. The microelectronic device of claim 11, wherein the first memory array structure further comprises first digit line structures, and wherein the first shield structure vertically overlies and horizontally extends across and between the first digit line structures of the first memory array structure.

15. The microelectronic device of claim 14, wherein the first shield structure comprises first projections horizontally alternating with and vertically overlapping the first digit line structures of the first memory array structure.

16. A microelectronic device, comprising:
a first assembly oriented on and attached to a shared carrier, the first assembly comprising:
a first memory array structure comprising first dynamic random-access memory (DRAM) cells respectively comprising a vertical channel transistor coupled to a capacitor;
a first control circuitry structure vertically overlying and attached to the first memory array structure;
a first shield contact formed proximate a horizontal boundary of the first assembly; and
a first shield structure operably coupled to the first shield contact and vertically interposed between the first DRAM cells of the first memory array structure and the first control circuitry structure; and
a second assembly oriented on and attached to the shared carrier and horizontally neighboring the first assembly, the second assembly comprising:
a second memory array structure comprising second DRAM cells respectively comprising an additional vertical channel transistor coupled to an additional capacitor;
a second control circuitry structure vertically overlying and attached to the second memory array structure;
a second shield contact formed proximate a horizontal boundary of the second assembly; and
a second shield structure operably coupled to the second shield contact and vertically interposed between the second DRAM cells of the second memory array structure and the second control circuitry structure,
wherein the horizontal boundary of the first assembly most proximate the first shield contact is neighboring the horizontal boundary of the second assembly most proximate the second shield contact.

17. The microelectronic device of claim 16, wherein the shared carrier comprises semiconductor material overlying a cell plate.

18. The microelectronic device of claim 17, wherein the cell plate comprises an electrode of a shared multi-capacitor structure.

19. The microelectronic device of claim 18, further comprising:
at least one first contact assembly operably coupled to the cell plate of the shared carrier by way of a first cell plate contact proximate a horizontal boundary of a patch region at a longitudinal end of the patch region of the microelectronic device; and
at least one second contact assembly operably coupled to the cell plate of the shared carrier by way of a second cell plate contact proximate a horizontal boundary of the patch region at a lateral end of the patch region of the microelectronic device.

20. The microelectronic device of claim 19, wherein both of the at least one first contact assembly and the at least one second contact assembly extend through the semiconductor material of the shared carrier.
